(19) United States
(12) Patent Application Publication
(10) Pub. No.: US 2023/0232678 A1
(43) Pub. Date: Jul. 20, 2023

(54) DISPLAY DEVICE

(71) Applicant: SAMSUNG DISPLAY CO., LTD., Yongin-si (KR)

(72) Inventors: Jaehyung CHO, Yongin-si (KR); Seonyoung CHOI, Yongin-si (KR)

(21) Appl. No.: 18/075,823

(22) Filed: Dec. 6, 2022

(30) Foreign Application Priority Data
Jan. 18, 2022 (KR) 10-2022-0007347

(51) Int. Cl. H10K 59/131; G09G 3/3233

(52) U.S. Cl. CPC H01L 27/3276; G09G 3/3233; H01L 27/3211

(57) ABSTRACT

A display device includes a substrate which includes a display area and in which a first opening area is defined, and a non-display area which includes a first driving circuit area and a second driving circuit area adjacent to the first driving circuit area, and in which a second opening area is defined between the first driving circuit area and the second driving circuit area, and a circuit layer disposed on the substrate and including a first driving circuit overlapping the first driving circuit area and including a first conductive pattern and a second driving circuit overlapping the second driving circuit area and including a second conductive pattern. A shape of the first conductive pattern and a shape of the second conductive pattern are inverted from each other based on a first virtual straight line passing through a center of the first driving circuit area and a center of the second driving circuit area in a plan view.

This application claims priority to Korean Patent Application No. 10-2022-0007347, filed on Jan. 18, 2022, and all the benefits accruing therefrom under 35 U.S.C. § 119, the content of which in its entirety is herein incorporated by reference.

### BACKGROUND

### 1. Field

Embodiments relate to a display device.

### 2. Description of the Related Art

As display devices for visually displaying electrical signals have been developed, various display devices having excellent characteristics, such as thinness, lightweight, and low power consumption, are being introduced. Flexible display devices that may be folded or rolled into a roll shape are being introduced, for example. Recently, research and development on a stretchable display device that may be changed into various forms are actively progressing.

The display device may include a display area in which a pixel circuit and a light-emitting device electrically connected to the pixel circuit are arranged, and a non-display area in which a driving circuit for applying an electrical signal to the pixel circuit is arranged.

### SUMMARY

Embodiments include a display device that is deformable into various shapes in a display area and a non-display area.

Additional features will be set forth in part in the description which follows and, in part, will be apparent from the description, or may be learned by practice of the presented embodiments of the invention.

In an embodiment of the invention, a display device includes a substrate including a display area in which a first opening area is defined and a non-display area which includes a first driving circuit area and a second driving circuit area adjacent to the first driving circuit area, and in which a second opening area is defined between the first driving circuit area and the second driving circuit area, and a circuit layer disposed on the substrate and including a first driving circuit overlapping the first driving circuit area and including a first conductive pattern and a second driving circuit overlapping the second driving circuit area and including a second conductive pattern. A shape of the first conductive pattern and a shape of the second conductive pattern are inverted from each other based on a first virtual straight line passing through a center of the first driving circuit area and a center of the second driving circuit area in a plan view.

In an embodiment, the circuit layer may further include a first wire connected to the first driving circuit and extending from the first driving circuit and a second wire connected to the second driving circuit and extending from the second driving circuit. A shape of the first wire in the first driving circuit area and a shape of the second wire in the second driving circuit area may be inverted from each other based on the first virtual straight line in the plan view.

In an embodiment, the non-display area may further include a third driving circuit area arranged in a first direction with the first driving circuit area and a fourth driving circuit area adjacent to the third driving circuit area and arranged in the first direction with the second driving circuit area, a third opening area may be defined in the non-display area between the third driving circuit area and the fourth driving circuit area, and the circuit layer may further include a third driving circuit overlapping the third driving circuit area and including a third conductive pattern and a fourth driving circuit overlapping the fourth driving circuit area and including a fourth conductive pattern. A shape of the third conductive pattern and a shape of the fourth conductive pattern may be inverted from each other based on a second virtual straight line passing through a center of the third driving circuit area and a center of the fourth driving circuit area in the plan view.

In an embodiment, the non-display area may further include a first wire area between the first driving circuit area and the third driving circuit area, a first intermediate connection area extending from the first driving circuit area to the first wire area, a second intermediate connection area extending from the first wire area to the third driving circuit area, a second wire area between the second driving circuit area and the fourth driving circuit area, a third intermediate connection area extending from the second driving circuit area to the second wire area, and a fourth intermediate connection area extending from the second wire area to the fourth driving circuit area. A width of the first driving circuit area, a width of the first wire area, and a width of the third driving circuit area may be the same.

In an embodiment, each of the first driving circuit and the second driving circuit is a scan driving circuit that generates a scan signal, and each of the third driving circuit and the fourth driving circuit is an emission control driving circuit that generates an emission control signal.

In an embodiment, the display area may further include a first pixel area and a second pixel area adjacent to the first pixel area, the first opening area may be between the first pixel area and the second pixel area, the circuit layer may further include a first pixel circuit overlapping the first pixel area and a second pixel circuit overlapping the second pixel area, and the display device further including a light-emitting device layer disposed on the circuit layer and including a first light-emitting device overlapping the first pixel area and connected to the first pixel circuit and a second light-emitting device overlapping the second pixel area and connected to the second pixel circuit. The first pixel area may be between the first driving circuit area and the third driving circuit area.

In an embodiment, the non-display area may further include a third driving circuit area having a center overlapping the first virtual straight line and adjacent to the second driving circuit area, a fourth driving circuit area having a center overlapping the first virtual straight line and adjacent to the third driving circuit area, a first base area arranged in a first direction with the first driving circuit area, a second base area arranged in the first direction with the second driving circuit area, a third base area arranged in the first direction with the third driving circuit area, and a fourth base area arranged in the first direction with the fourth driving circuit area, and the circuit layer may include a third driving circuit overlapping the third driving circuit area and including a third conductive pattern, a fourth driving circuit overlapping the fourth driving circuit area and including a fourth conductive pattern, a fifth driving circuit including a first partial driving circuit overlapping the first base area and including a first partial conductive pattern and a second partial driving circuit overlapping the second base area and including a second partial conductive pattern, and a sixth driving circuit including a third partial driving circuit overlapping the third base area and including a third partial conductive pattern and a fourth partial driving circuit overlapping the fourth base area and including a fourth partial conductive pattern. A shape of the first partial conductive pattern and a shape of the third partial conductive pattern are inverted from each other based on a third virtual straight line passing through a center of the first base area and a center of the third base area in the plan view, and a shape of the second partial conductive pattern and a shape of the fourth partial conductive pattern may be inverted from each other based on the third virtual straight line in the plan view.

In an embodiment, the non-display area may further include a third driving circuit area having a center overlapping the first virtual straight line and adjacent to the second driving circuit area, a fourth driving circuit area having a center overlapping the first virtual straight line and adjacent to the third driving circuit area, a first base area arranged in a first direction with the first driving circuit area, a second base area arranged in the first direction with the second driving circuit area, a third base area arranged in the first direction with the third driving circuit area, and a fourth base area arranged in the first direction with the fourth driving circuit area, and the circuit layer may include a third driving circuit overlapping the third driving circuit area and including a third conductive pattern, a fourth driving circuit overlapping the fourth driving circuit area and including a fourth conductive pattern, a fifth driving circuit including a fifth conductive pattern overlapping the first base area, and a sixth driving circuit including a sixth conductive pattern overlapping the fourth base area. A shape of the third conductive pattern and a shape of the fourth conductive pattern may be inverted from each other based on the first virtual straight line in the plan view, and a shape of the fifth conductive pattern and a shape of the sixth conductive pattern may be inverted from each other based on a fourth virtual straight line passing through a center of the first base area and a center of the fourth base area in the plan view.

In an embodiment, the display area may further include a first pixel area and a second pixel area adjacent to the first pixel area, the first opening area may be between the first pixel area and the second pixel area, the circuit layer may further include a first pixel circuit overlapping the first pixel area and a second pixel circuit overlapping the second pixel area, and the display device further including a light-emitting device layer disposed on the circuit layer and including a first light-emitting device overlapping the first pixel area and connected to the first pixel circuit and a second light-emitting device overlapping the second pixel area and connected to the second pixel circuit. A width of the first pixel area may be the same as a width of the first driving circuit area.

In an embodiment, the display area may further include a first connection area extending from the first pixel area to the second pixel area, and the non-display area may further include a second connection area extending from the first driving circuit area to the second driving circuit area. In the plan view, an edge of the first pixel area, an edge of the second pixel area, and an edge of the first connection area define at least a portion of the first opening area, and in the plan view, an edge of the first driving circuit area, an edge of the second driving circuit area, and an edge of the second connection area define at least a portion of the second opening area. A width of the first connection area may be the same as a width of the second connection area.

In an embodiment of the invention, a display device includes a substrate including a display area in which a first opening area is defined and a non-display area which includes a first driving circuit area, a second driving circuit area adjacent to the first driving circuit area, and in which a second opening area is defined between the first driving circuit area and the second driving circuit area, and a circuit layer disposed on the substrate and including a first driving circuit overlapping the first driving circuit area, a first wire connected to the first driving circuit, a second driving circuit overlapping the second driving circuit area, and a second wire connected to the second driving circuit. A shape of the first wire in the first driving circuit area and a shape of the second wire in the second driving circuit area are inverted from each other based on a first virtual straight line passing through a center of the first driving circuit area and a center of the second driving circuit area in a plan view.

In an embodiment, the first driving circuit may include a first conductive pattern, and the second driving circuit may include a second conductive pattern. A shape of the first conductive pattern and a shape of the second conductive pattern may be inverted from each other based on the first virtual straight line in the plan view.

In an embodiment, the non-display area may further include a third driving circuit area arranged in a first direction with the first driving circuit area and a fourth driving circuit area adjacent to the third driving circuit area and arranged in the first direction with the second driving circuit area, a third opening area may be defined between the third driving circuit area and the fourth driving circuit area, and the circuit layer may further include a third driving circuit overlapping the third driving circuit area and including a third conductive pattern and a fourth driving circuit overlapping the fourth driving circuit area and including a fourth conductive pattern. A shape of the third conductive pattern and a shape of the fourth conductive pattern may be inverted from each other based on a second virtual straight line passing through a center of the third driving circuit area and a center of the fourth driving circuit area in the plan view.

In an embodiment, the non-display area may further include a first wire area between the first driving circuit area and the third driving circuit area, a first intermediate connection area extending from the first driving circuit area to the first wire area, a second intermediate connection area extending from the first wire area to the third driving circuit area, a second wire area between the second driving circuit area and the fourth driving circuit area, a third intermediate connection area extending from the second driving circuit area to the second wire area, and a fourth intermediate connection area extending from the second wire area to the fourth driving circuit area. A width of the first driving circuit area, a width of the first wire area, and a width of the third driving circuit area may be the same.

In an embodiment, each of the first driving circuit and the second driving circuit is a scan driving circuit that generates a scan signal, and each of the third driving circuit and the fourth driving circuit is an emission control driving circuit that generates an emission control signal.

In an embodiment, the display area may further include a first pixel area and a second pixel area adjacent to the first pixel area, the first opening area may be between the first pixel area and the second pixel area, the circuit layer may further include a first pixel circuit overlapping the first pixel area and a second pixel circuit overlapping the second pixel area, and the display device further including a light-emitting device layer disposed on the circuit layer and including a first light-emitting device overlapping the first pixel area and connected to the first pixel circuit and a second light-emitting device overlapping the second pixel area and connected to the second pixel circuit. The first pixel area may be between the first driving circuit area and the third driving circuit area.

In an embodiment, the non-display area may further include a third driving circuit area having a center overlapping the first virtual straight line and adjacent to the second driving circuit area, a fourth driving circuit area having a center overlapping the first virtual straight line and adjacent to the third driving circuit area, a first base area arranged in a first direction with the first driving circuit area, a second base area arranged in the first direction with the second driving circuit area, a third base area arranged in the first direction with the third driving circuit area, and a fourth base area arranged in the first direction with the fourth driving circuit area, and the circuit layer may include a third driving circuit overlapping the third driving circuit area and including a third conductive pattern, a fourth driving circuit overlapping the fourth driving circuit area and including a fourth conductive pattern, a fifth driving circuit including a first partial driving circuit overlapping the first base area and including a first partial conductive pattern and a second partial driving circuit overlapping the second base area and including a second partial conductive pattern, and a sixth driving circuit including a third partial driving circuit overlapping the third base area and including a third partial conductive pattern and a fourth partial driving circuit overlapping the fourth base area and including a fourth partial conductive pattern. A shape of the first partial conductive pattern and a shape of the third partial conductive pattern are inverted from each other based on a third virtual straight line passing through a center of the first base area and a center of the third base area in the plan view, and a shape of the second partial conductive pattern and a shape of the fourth partial conductive pattern may be inverted from each other based on the third virtual straight line in the plan view.

In an embodiment, the non-display area may further include a third driving circuit area having a center overlapping the first virtual straight line and adjacent to the second driving circuit area, a fourth driving circuit area having a center overlapping the first virtual straight line and adjacent to the third driving circuit area, a first base area arranged in a first direction with the first driving circuit area, a second base area arranged in the first direction with the second driving circuit area, a third base area arranged in the first direction with the third driving circuit area, and a fourth base area arranged in the first direction with the fourth driving circuit area, and the circuit layer may include a third driving circuit overlapping the third driving circuit area and including a third conductive pattern, a fourth driving circuit overlapping the fourth driving circuit area and including a fourth conductive pattern, a fifth driving circuit including a fifth conductive pattern overlapping the first base area, and a sixth driving circuit including a sixth conductive pattern overlapping the fourth base area. A shape of the third conductive pattern and a shape of the fourth conductive pattern may be inverted from each other based on the first virtual straight line in the plan view, and a shape of the fifth conductive pattern and a shape of the sixth conductive pattern may be inverted from each other based on a fourth virtual straight line passing through a center of the first base area and a center of the fourth base area in the plan view.

In an embodiment, the display area may further include a first pixel area, a second pixel area adjacent to the first pixel area, and a first connection area extending from the first pixel area to the second pixel area, and the non-display area may further include a second connection area extending from the first driving circuit area to the second driving circuit area. In the plan view, an edge of the first pixel area, an edge of the second pixel area, and an edge of the first connection area define at least a portion of the first opening area, and in the plan view, an edge of the first driving circuit area, an edge of the second driving circuit area, and an edge of the second connection area define at least a portion of the second opening area, the circuit layer may further include a first pixel circuit overlapping the first pixel area and a second pixel circuit overlapping the second pixel area, and the display device further including a light-emitting device layer disposed on the circuit layer and including a first light-emitting device overlapping the first pixel area and connected to the first pixel circuit and a second light-emitting device overlapping the second pixel area and connected to the second pixel circuit. In the plan view, a width of the first pixel area, a width of the second pixel area, a width of the first driving circuit area, and a width of the second driving circuit area are the same as each other, and a width of the first connection area may be the same as a width of the second connection area.

In an embodiment, the circuit layer may further include a first planarization layer overlapping the second connection area and a second planarization layer disposed on the first planarization layer, and the first wire may extend from the first driving circuit area to the second connection area and may be between the first planarization layer and the second planarization layer.

### BRIEF DESCRIPTION OF THE DRAWINGS

The above and other features and advantages of embodiments of the invention will be more apparent from the following description taken in conjunction with the accompanying drawings, in which:

FIG. 1 is a schematic perspective view of an embodiment of a display device;

FIG. 2A is a perspective view illustrating a first state in which the display device of FIG. 1 is stretched in a first direction;

FIG. 2B is a perspective view illustrating a second state in which the display device of FIG. 1 is stretched in a second direction;

FIG. 3 is a schematic plan view of an embodiment of a display device;

FIGS. 4A and 4B are equivalent circuit diagrams schematically illustrating one pixel of a display device, respectively;

FIG. 5 is a schematic view of an embodiment of a driving circuit;

FIG. 6 is a schematic plan view of an embodiment of enlarged portion A of the display device of FIG. 3;

FIG. 7A is a schematic cross-sectional view of the display device of FIG. 6, taken along line B-B′;

FIG. 7B is a schematic cross-sectional view of the display device of FIG. 6, taken along line C-C′;

FIG. 7C is a schematic cross-sectional view of the display device of FIG. 6, taken along line D-D′;

FIG. 8 is a plan view illustrating an embodiment of a deformed state of the display device of FIG. 6 when a tensile force is applied to the display device;

FIG. 9A is a view of a simulation result illustrating another embodiment of a deformed state of the display device of FIG. 6 when a tensile force or a contractile force is applied to the display device;

FIG. 9B is a plan view illustrating another embodiment of a deformed state of the display device of FIG. 6 when a tensile force is applied to the display device;

FIG. 10 is a schematic plan view of an embodiment of enlarged portion E of the display device of FIG. 3;

FIG. 11 is an enlarged plan view of another embodiment of portion E of the display device of FIG. 3;

FIG. 12 is a schematic plan view of an embodiment of a non-display area of the display device of FIG. 3;

FIG. 13 is a schematic plan view of another embodiment of a non-display area of the display device of FIG. 3; and

FIG. 14 is an enlarged plan view of portion F, portion G, and portion H of the display device of FIG. 6.

### DETAILED DESCRIPTION

Reference will now be made in detail to embodiments, embodiments of which are illustrated in the accompanying drawings, where like reference numerals refer to like elements throughout. In this regard, the illustrated embodiments may have different forms and should not be construed as being limited to the descriptions set forth herein. Accordingly, the embodiments are merely described below, by referring to the drawing figures, to explain features of the description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

Since the disclosure may have diverse modified embodiments, certain embodiments are illustrated in the drawings and are described in the detailed description. Advantages and features of the invention, and implementation methods thereof will be clarified through following embodiments described with reference to the accompanying drawings. The disclosure may, however, be embodied in many different forms and should not be construed as limited to the embodiments set forth herein.

Hereinafter, embodiments of the invention will be described in detail with reference to the accompanying drawings. The same reference numerals are used to denote the same elements, and repeated descriptions thereof will be omitted.

It will be understood that although the terms “first,” “second,” etc. may be used herein to describe various elements, these elements should not be limited by these terms.

An expression used in the singular encompasses the expression of the plural, unless it has a clearly different meaning in the context.

It will be further understood that the terms “comprises” and/or “comprising” used herein specify the presence of stated features or elements, but do not preclude the presence or addition of one or more other features or elements.

It will be understood that when a layer, area, or element is referred to as being “formed on” another layer, area, or element, it may be directly or indirectly formed on the other layer, area, or element. That is, intervening layers, areas, or elements may be present, for example.

Sizes of elements in the drawings may be exaggerated for convenience of description. In other words, since sizes and thicknesses of components in the drawings are arbitrarily illustrated for convenience of description, the invention is not limited thereto.

When an embodiment may be implemented differently, a predetermined process order may be performed differently from the described order. Two consecutively described processes may be performed substantially at the same time or performed in an order opposite to the described order, for example.

It will be understood that when a layer, region, or component is connected to another portion, the layer, region, or component may be directly connected to the portion or an intervening layer, region, or component may exist. When a layer, region, or component is electrically connected to another portion, the layer, region, or component may be directly electrically connected to the portion or may be indirectly connected to the portion through another layer, region, or component, for example.

In the specification, the term “A and/or B” refers to the case of A or B, or A and B. In the specification, the term “at least one of A and B” refers to the case of A or B, or A and B.

In the following embodiments, “ON” used in connection with a device state may refer to an activated state of the device, and “OFF” may refer to an inactive state of the device. As used in connection with a signal received by the device, “ON” may refer to a signal that activates the device, and “OFF” refers to a signal that deactivates the device. The device may be activated by either a high voltage or a low voltage. Hereinafter, a voltage that turns on a transistor is referred to as an on voltage, and a voltage that turns off a transistor is referred to as an off voltage.

The display device is a device for displaying an image, and may be a portable mobile device, such as a game console, a multimedia device, or a micro PC. The display device may include liquid crystal displays, electrophoretic displays, organic light-emitting displays, inorganic light-emitting displays, field emission displays, surface-conduction electron-emitter displays, quantum dot displays, plasma displays, and cathode ray displays. Hereinafter, although an organic light-emitting display will be described in an embodiment of the display device, various kinds of display devices as described above may be used in embodiments.

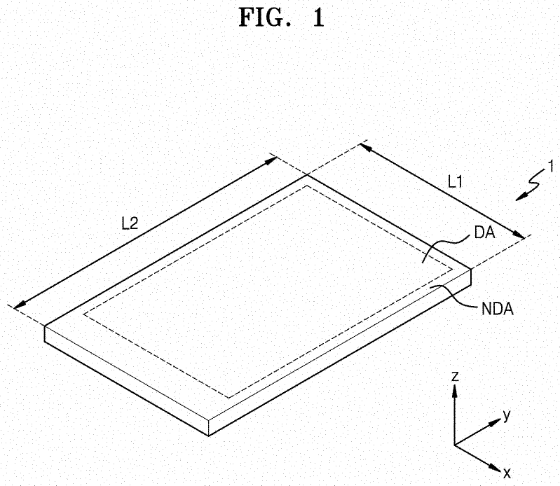

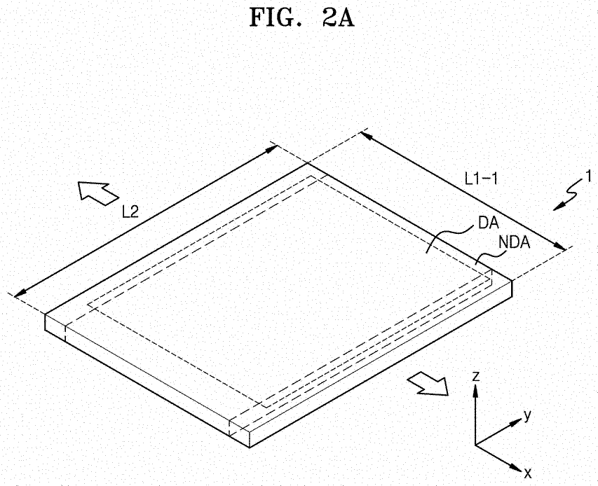

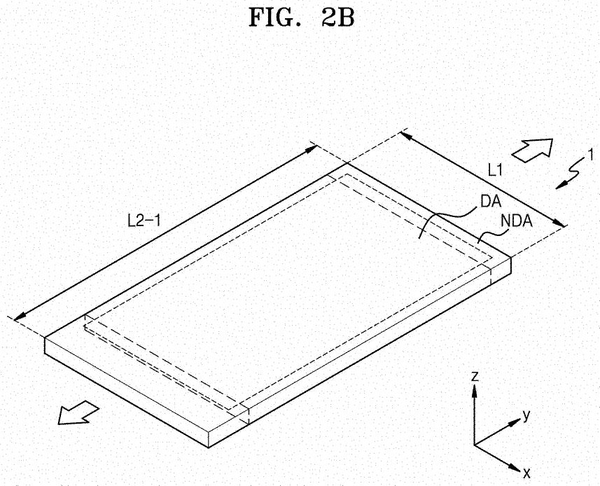

FIG. 1 is a perspective view of an embodiment of a display device 1. FIG. 2A is a perspective view illustrating a first state in which the display device 1 of FIG. 1 is stretched in a first direction. FIG. 2B is a perspective view illustrating a second state in which the display device 1 of FIG. 1 is stretched in a second direction.

Referring to FIG. 1, the display device 1 may display an image. The display device 1 may include a display area DA and a non-display area NDA. A plurality of pixels may be arranged in the display area DA, and the display device 1 may provide a predetermined image using light emitted from the plurality of pixels. The non-display area NDA may be adjacent to the display area DA. The non-display area NDA may at least partially surround the display area DA. In an embodiment, the non-display area NDA may surround the display area DA.

The display device 1 may include a first side L1 extending in the first direction and a second side L2 extending in the second direction. The first side L1 and the second side L2 may be edges of the display device 1. The first direction and the second direction may cross each other. In an embodiment, the first direction and the second direction may define an acute angle, for example. In another embodiment, the first direction and the second direction may define an obtuse angle or be orthogonal to each other. Hereinafter, a case in which the first direction is an x direction or a −x direction and the second direction is a y direction or a −y direction will be described in detail.

Referring to FIGS. 2A and 2B, the display device 1 may be a stretchable display device. Referring to FIG. 2A, when a tensile force is applied to the display device 1 in the first direction (e.g., the x-direction or the −x-direction), the display device 1 may be stretched in the first direction (e.g., the x-direction or the −x-direction). In this case, a first side L1-1 of FIG. 2A may be longer than the first side L1 of FIG. 1. Each of the display area DA and the non-display area NDA may be stretched in the first direction (e.g., the x-direction or the −x-direction). In another embodiment, when a contractile force is applied to the display device 1 in the first direction (e.g., the x-direction or the −x-direction), the display device 1 may be contracted in the first direction (e.g., the x-direction or the −x-direction). In this case, the first side L1-1 of FIG. 2A may be shorter than the first side L1 of FIG. 1. Each of the display area DA and the non-display area NDA may be contracted in the first direction (e.g., the x-direction or the −x-direction).

Referring to FIG. 2B, when a tensile force is applied to the display device 1 in the second direction (e.g., the y-direction or the −y-direction), the display device 1 may be stretched in the second direction (e.g., the y-direction or the −y-direction). In this case, a second side L2-1 of FIG. 2B may be longer than the second side L2 of FIG. 1. Each of the display area DA and the non-display area NDA may be stretched in the second direction (e.g., the y-direction or the −y-direction). In another embodiment, when a contractile force is applied to the display device 1 in the second direction (e.g., the y-direction or the −y-direction), the display device 1 may be contracted in the second direction (e.g., the y-direction or the −y-direction). In this case, the second side L2-1 of FIG. 2B may be shorter than the second side L2 of FIG. 1. Each of the display area DA and the non-display area NDA may be contracted in the second direction (e.g., the y-direction or the −y-direction). As described above, when a tensile force or a contractile force is applied to the display device 1, the display device 1 may be deformed into various shapes.

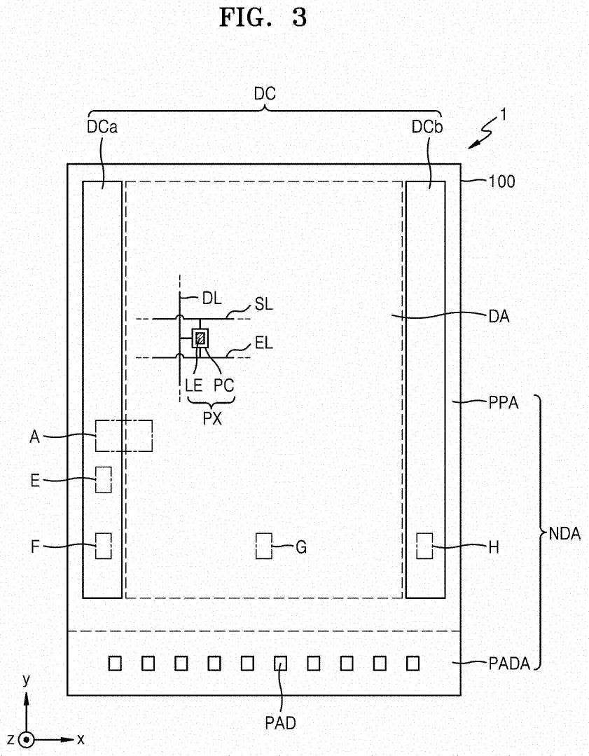

FIG. 3 is a plan view of an embodiment of the display device 1.

Referring to FIG. 3, the display device 1 may include a substrate 100, a pixel PX, a scan line SL, a data line DL, an emission control line EL, a driving circuit DC, and a pad PAD. The display device 1 may include the display area DA and the non-display area NDA. In an embodiment, the display area DA and the non-display area NDA may be defined in the substrate 100. In an embodiment, the substrate 100 may include the display area DA and the non-display area NDA, for example.

The pixel PX may be arranged in the display area DA. The non-display area NDA may be adjacent to the display area DA. In an embodiment, the non-display area NDA may at least partially surround the display area DA. In an embodiment, the non-display area NDA may surround the display area DA, for example. The non-display area NDA may include a peripheral area PPA and a pad area PADA. The peripheral area PPA may be adjacent to the display area DA. The driving circuit DC for applying an electrical signal to the pixel PX may be arranged in the peripheral area PPA. The pad area PADA may be on one side of the peripheral area PPA. The pad PAD may be arranged in the pad area PADA.

The pixel PX may be arranged in the display area DA. In an embodiment, a plurality of pixels PX may be provided in the display area DA. The pixel PX may include a pixel circuit PC and a light-emitting device LE.

The pixel circuit PC may be a circuit that controls the light-emitting device LE. A plurality of pixel circuits PC may be provided in the display area DA. The pixel circuit PC may include at least one transistor and at least one storage capacitor. In an embodiment, the pixel circuit PC may be electrically connected to the scan line SL and the data line DL. In an embodiment, the pixel circuit PC may be electrically connected to the scan line SL, the emission control line EL, and the data line DL.

The light-emitting device LE may be electrically connected to the pixel circuit PC. A plurality of light-emitting devices LE may be provided in the display area DA. The light-emitting device LE may be an organic light-emitting diode including an organic emission layer. In an alternative embodiment, the light-emitting device LE may be a light-emitting diode LED including an inorganic emission layer. A size of the light-emitting diode LED may be micro-scale or nano-scale. In an embodiment, the light-emitting diode LED may be a micro light-emitting diode, for example. In an alternative embodiment, the light-emitting diode LED may be a nanorod light-emitting diode. The nanorod light-emitting diode may include gallium nitride (GaN). In an embodiment, a color conversion layer may be on the nanorod light-emitting diode. The color conversion layer may include quantum dots. In an alternative embodiment, the light-emitting device LE may be a quantum dot light-emitting diode including a quantum dot emission layer. Hereinafter, it will be described in detail focusing on a case where the light-emitting device LE is an organic light-emitting diode.

The scan line SL may extend in the first direction (e.g., the x-direction or the −x-direction). The scan line SL may be electrically connected to the driving circuit DC. In an embodiment, the scan line SL may be electrically connected to a scan driving circuit generating a scan signal from among driving circuits DC. The scan line SL may be electrically connected to the pixel circuit PC. The scan line SL may receive a scan signal from the scan driving circuit and transmit the scan signal to the pixel circuit PC.

The data line DL may extend in the second direction (e.g., the y direction or the −y direction). The data line DL may be electrically connected to a data driving circuit (not shown). The data line DL may be electrically connected to the pixel circuit PC. The data line DL may receive a data signal from the data driving circuit and transmit the data signal to the pixel circuit PC.

The emission control line EL may extend in the first direction (e.g., the x-direction or the −x-direction). The emission control line EL may be electrically connected to the driving circuit DC. In an embodiment, the emission control line EL may be electrically connected to an emission control driving circuit generating an emission control signal from among the driving circuits DC. The emission control line EL may be electrically connected to the pixel circuit PC. The emission control line EL may receive the emission control signal from the emission control driving circuit and transmit the emission control signal to the pixel circuit PC.

The driving circuit DC may be arranged in the peripheral area PPA. The driving circuit DC may be on one side of the display area DA. In an embodiment, the driving circuit DC may extend in the second direction (e.g., the y direction or the −y direction). In an embodiment, the driving circuit DC may include a left driving circuit DCa and a right driving circuit DCb. The left driving circuit DCa may be on the left side of the display area DA. The right driving circuit DCb may be on the right side of the display area DA. The display area DA may be between the left driving circuit DCa and the right driving circuit DCb. In some embodiments, any one of the left driving circuit DCa and the right driving circuit DCb may be omitted. In some embodiments, the left driving circuit DCa and the right driving circuit DCb may include a scan driving circuit and an emission control driving circuit, respectively. In some embodiments, the left driving circuit DCa may include a scan driving circuit and the right driving circuit DCb may include an emission control driving circuit. In some embodiments, the left driving circuit DCa may include an emission control driving circuit and the right driving circuit DCb may include a scan driving circuit.

The pad PAD may be arranged in the pad area PADA. A plurality of pads PAD may be provided in the pad area PADA. A display driver (not shown) and/or a display circuit board may be arranged in the pad area PADA, and the pad PAD may be electrically connected to the display driver and/or the display circuit board.

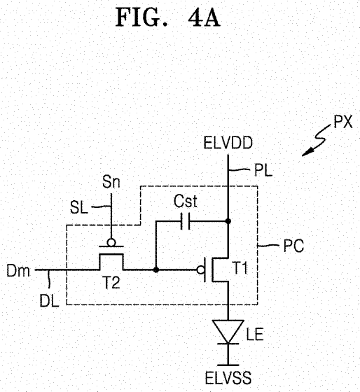

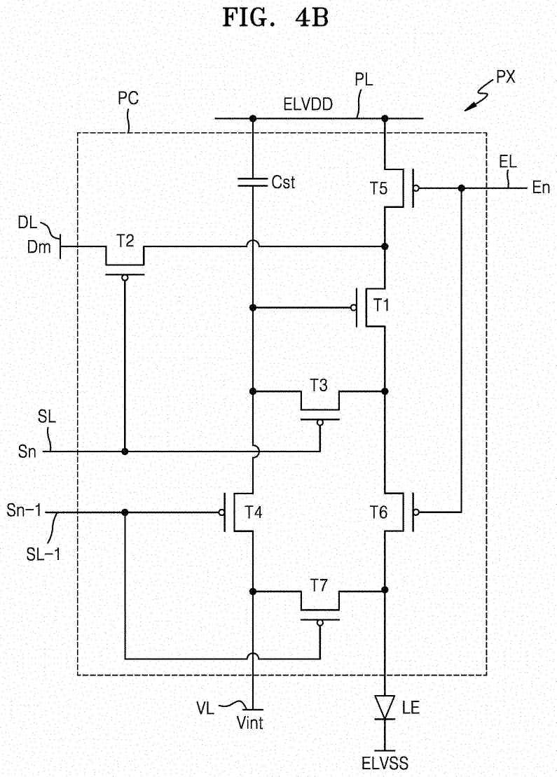

FIGS. 4A and 4B are equivalent circuit diagrams schematically illustrating one pixel PX of a display device, respectively.

Referring to FIG. 4A, the pixel PX may include the pixel circuit PC and the light-emitting device LE electrically connected to the pixel circuit PC. In an embodiment, the pixel circuit PC may include a driving transistor T1, a switching transistor T2, and a storage capacitor Cst.

The switching transistor T2 may be connected to the scan line SL and the data line DL, and may transmit a data signal Dm input from the data line DL to the driving transistor T1 according to a scan signal Sn input from the scan line SL.

The storage capacitor Cst may be connected to the switching transistor T2 and a driving voltage line PL, and may store a voltage corresponding to a difference between a voltage received from the switching transistor T2 and a first power voltage ELVDD supplied to a driving voltage line PL.

The driving transistor T1 may be connected to the driving voltage line PL and the storage capacitor Cst, and may control a driving current flowing from the driving voltage line PL to the light-emitting device LE in response to a voltage value stored in the storage capacitor Cst. The light-emitting device LE may emit light having a predetermined luminance according to a driving current. An opposite electrode (e.g., a cathode) of the light-emitting device LE may be supplied with a second power voltage ELVSS.

Although FIG. 4A illustrates that the pixel circuit PC includes two transistors and one storage capacitor, in another embodiment, the pixel circuit PC may include three or more transistors and two or more capacitors.

Referring to FIG. 4B, the pixel PX may include the pixel circuit PC and the light-emitting device LE. The pixel circuit PC may include the driving transistor T1, the switching transistor T2, a compensation transistor T3, a first initialization transistor T4, an operation control transistor T5, an emission control transistor T6, and a second initialization transistor T7.

FIG. 4B illustrates a case in which the scan line SL, a previous scan line SL-1, the emission control line EL, the data line DL, an initialization voltage line VL, and the driving voltage line PL are provided for each pixel circuit PC, but in another embodiment, at least one of the scan line SL, the previous scan line SL-1, the emission control line EL, the data line DL, and the initialization voltage line VL may be shared by neighboring pixel circuits.

A driving drain electrode of the driving transistor T1 may be electrically connected to the light-emitting device LE via the emission control transistor T6. The driving transistor T1 may receive the data signal Dm according to a switching operation of the switching transistor T2 to supply a driving current to the light-emitting device LE.

A switching gate electrode of the switching transistor T2 may be connected to the scan line SL, and a switching source electrode may be connected to the data line DL. A switching drain electrode of the switching transistor T2 may be connected to a source electrode of the driving transistor T1 and may be connected to the driving voltage line PL via the operation control transistor T5. The switching transistor T2 may be turned on according to the scan signal Sn received through the scan line SL to perform a switching operation of transmitting the data signal Dm transmitted to the data line DL to a driving source electrode of the driving transistor T1.

A compensation gate electrode of the compensation transistor T3 may be connected to the scan line SL. A compensation source electrode of the compensation transistor T3 may be connected to the driving drain electrode of the driving transistor T1 and connected to a pixel electrode of the light-emitting device LE via the emission control transistor T6. A compensation drain electrode of the compensation transistor T3 may be connected together with any one electrode of the storage capacitor Cst, a first initialization source electrode of the first initialization transistor T4, and a driving gate electrode of the driving transistor T1. The compensation transistor T3 is turned on according to the scan signal Sn received through the scan line SL to connect the driving gate electrode and the driving drain electrode of the driving transistor T1 to each other, thereby diode-connecting the driving transistor T1.

A first initialization gate electrode of the first initialization transistor T4 may be connected to the previous scan line SL-1. A first initialization drain electrode of the first initialization transistor T4 may be connected to the initialization voltage line VL. The first initialization source electrode of the first initialization transistor T4 may be connected together with any one electrode of the storage capacitor Cst, the compensation drain electrode of the compensation transistor T3, and the driving gate electrode of the driving transistor T1. The first initialization transistor T4 may be turned on according to a previous scan signal Sn-1 received through the previous scan line SL-1 to transmit an initialization voltage Vint to the driving gate electrode of the driving transistor T1 to perform an initialization operation for initializing a voltage of the driving gate electrode of the driving transistor T1.

An operation control gate electrode of the operation control transistor T5 may be connected to the emission control line EL. An operation control source electrode of the operation control transistor T5 may be connected to the driving voltage line PL. An operation control drain electrode of the operation control transistor T5 may be connected to the driving source electrode of the driving transistor T1 and the switching drain electrode of the switching transistor T2.

An emission control gate electrode of the emission control transistor T6 may be connected to the emission control line EL. An emission control source electrode of the emission control transistor T6 may be connected to the driving drain electrode of the driving transistor T1 and the compensation source electrode of the compensation transistor T3. An emission control drain electrode of the emission control transistor T6 may be electrically connected to the pixel electrode of the light-emitting device LE. The operation control transistor T5 and the emission control transistor T6 are simultaneously turned on according to an emission control signal En received through the emission control line EL, and thus, the first power voltage ELVDD is transmitted to the light-emitting device LE, and a driving current flows through the light-emitting device LE.

A second initialization gate electrode of the second initialization transistor T7 may be connected to the previous scan line SL-1. The second initialization source electrode of the second initialization transistor T7 may be connected to the pixel electrode of the light-emitting device LE. A second initialization drain electrode of the second initialization transistor T7 may be connected to the initialization voltage line VL. The second initialization transistor T7 may be turned on according to the previous scan signal Sn-1 received through the previous scan line SL-1 to initialize the pixel electrode of the light-emitting device LE.

FIG. 4B illustrates a case in which both the first initialization transistor T4 and the second initialization transistor T7 are connected to the previous scan line SL-1, but in another embodiment, the first initialization transistor T4 and the second initialization transistor T7 may be connected to the previous scan line SL-1 and a subsequent scan line (not shown), respectively. In addition, the first initialization transistor T4 and the second initialization transistor T7 may be driven according to the previous scan signal Sn-1 and the subsequent scan signal, respectively.

The other electrode of the storage capacitor Cst may be connected to the driving voltage line PL. Any one electrode of the storage capacitor Cst may be connected together to the driving gate electrode of the driving transistor T1, the compensation drain electrode of the compensation transistor T3, and the first initialization source electrode of the first initialization transistor T4.

An opposite electrode (e.g., a cathode) of the light-emitting device LE may receive the second power voltage ELVSS. The light-emitting device LE may receive a driving current from the driving transistor T1 to emit light.

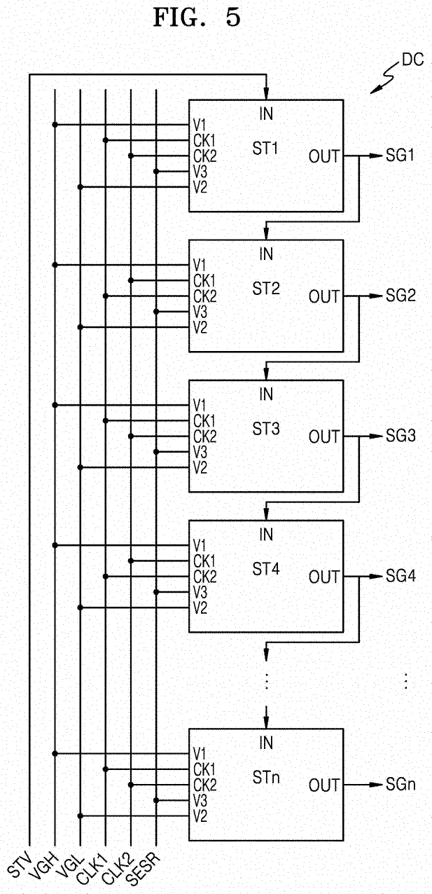

FIG. 5 is a view schematically illustrating an embodiment of the driving circuit DC.

Referring to FIG. 5, the driving circuit DC may include a plurality of stages. In an embodiment, the plurality of stages may include first to n^{th} stages ST1 to STn. Each of the first to n^{th} stages ST1 to STn may correspond to a pixel row (pixel line) provided in a display area, for example. The number of stages of the driving circuit DC may be variously modified according to the number of pixel rows. Each of the first to n^{th} stages ST1 to STn may include at least one transistor and at least one storage capacitor.

Each of the plurality of first to n^{th} stages ST1 to STn may output signals in response to a start signal or a previous signal. In an embodiment, a signal output from each of the first to n^{th} stages ST1 to STn may be the scan signal Sn or the previous scan signal Sn-1 applied to the pixel circuit PC of FIG. 4A or 4B. In an embodiment, a signal output from each of the first to n^{th} stages ST1 to STn may be the emission control signal En applied to the pixel circuit PC of FIG. 4B.

Each of the plurality of first to n^{th} stages ST1 to STn may include an input terminal IN, a first clock terminal CK1, a second clock terminal CK2, a first voltage input terminal V1, a second voltage input terminal V2, a third voltage input terminal V3, and an output terminal OUT.

The input terminal IN may receive an external signal STV or a previous signal as a start signal. In an embodiment, the external signal STV may be applied to the input terminal IN of the first stage ST1, and a previous signal output from the previous stage may be applied to the input terminal IN to each of the second to n^{th} stages ST2 to STn other than the first stage ST1. In an embodiment, the first stage ST1 may start driving by the external signal STV, and may generate and output a first signal SG1, for example. The second stage ST2 may start driving by the first signal SG1, and may generate and output a second signal SG2. An (n−1)th signal output from an (n−1)th stage is input to the input terminal IN of the n^{th} stage STn, and the n^{th} stage STn may generate and output an n^{th} signal SGn.

A first clock signal CLK1 or a second clock signal CLK2 may be applied to the first clock terminal CK1 and the second clock terminal CK2. In an embodiment, the first clock signal CLK1 and the second clock signal CLK2 may be alternately applied to the first to n^{th} stages ST1 to STn. In an embodiment, the first clock signal CLK1 may be applied to the first clock terminal CK1 of an odd-numbered stage, and the second clock signal CLK2 may be applied to the second clock terminal CK2, for example. In an embodiment, the second clock signal CLK2 may be applied to the first clock terminal CK1 of an even-numbered stage, and the first clock signal CLK1 may be applied to the second clock terminal CK2, for example.

The first voltage input terminal V1 may receive a first voltage VGH that is a high voltage, and the second voltage input terminal V2 may receive a second voltage VGL that is a low voltage. The first voltage VGH and the second voltage VGL may be rated voltages applied to the driving circuit DC. The first voltage VGH and the second voltage VGL may be supplied as global signals from a control unit and/or a power supply unit (not shown). The third voltage input terminal V3 may receive a third voltage SESR. The third voltage SESR may be a voltage for solving a glare problem of the display device. In some embodiments, the third voltage SESR may be omitted.

The output terminal OUT may output a signal. In an embodiment, the signal may be supplied to a pixel circuit as a scan signal or a previous scan signal through a scan line or a previous scan line. In an alternative embodiment, the signal may be supplied to the pixel circuit through an emission control line as an emission control signal. In an embodiment, the signal may be supplied to the input terminal IN of the next stage as a carry signal.

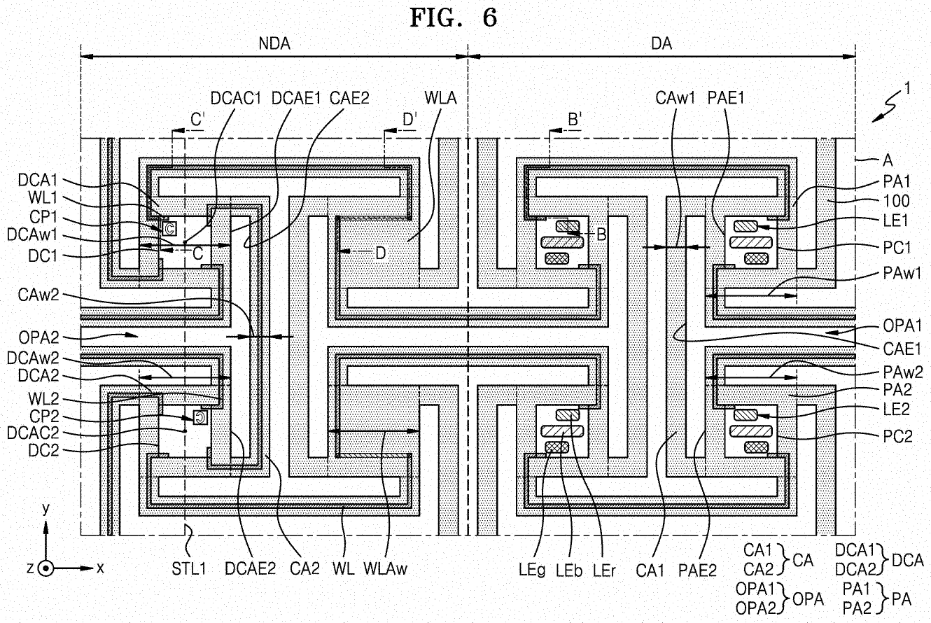

FIG. 6 is a schematic plan view of an embodiment of enlarged portion A of the display device 1 of FIG. 3.

Referring to FIG. 6, the display device 1 may include the substrate 100, a circuit layer, and a light-emitting device layer. In an embodiment, the substrate 100 may include the display area DA and the non-display area NDA, for example. The substrate 100 may include a base area and a connection area CA, and an opening area OPA may be defined in the substrate 100. The base area may be an area in which components of the display device 1 are arranged. A plurality of base areas may be provided. The plurality of base areas may be spaced apart from each other. The connection area CA may extend to or from adjacent base areas to each other. In this specification, when adjacent base areas are extended to each other by the connection area CA, it means that a connection area extends between adjacent base areas and the adjacent base areas and the connection area are unitary. A plurality of connection areas CA may be provided. The opening area OPA may be an area in which components of the display device 1 are not arranged. A plurality of opening areas OPA may be provided. In an embodiment, the opening area OPA may include a first opening area OPA1 and a second opening area OPA2, for example. The plurality of opening areas OPA may be spaced apart from each other. The plurality of base areas, the plurality of connection areas CA, and the plurality of opening areas OPA may be defined in the display area DA and/or the non-display area NDA.

The display area DA may include a pixel area PA and a first connection area CA1, and the opening area OPA may be defined in the display area DA. The pixel area PA may be a base area included in the display area DA. A plurality of pixel areas PA may be provided. The plurality of pixel areas PA may be arranged in the first direction (e.g., the x-direction or the −x-direction) and/or the second direction (e.g., the y-direction or the −y-direction). In an embodiment, the pixel area PA may include a first pixel area PA1 and a second pixel area PA2. The first pixel area PA1 and the second pixel area PA2 may be adjacent to each other.

The first connection area CA1 may be a first bridge area in the display area DA. In the display area DA, adjacent base areas may be extended to each other by the first connection area CA1. Adjacent pixel areas PA may be extended to each other by the first connection area CA1. In an embodiment, one pixel area PA may be extended to four first connection areas CA1, for example. The four first connection areas CA1 may extend from respective vertices of one pixel area PA. The four first connection areas CA1 may extend to adjacent pixel areas PA, respectively. Accordingly, the adjacent pixel areas PA may be extended to each other. In an embodiment, the first connection area CA1 may extend from the first pixel area PA1 to the second pixel area PA2. The first pixel area PA1 and the second pixel area PA2 may be extended to each other by the first connection area CA1. The first pixel area PA1, the first connection area CA1, and the second pixel area PA2 may be unitary.

An extending direction of the first connection area CA1 may be changed. In an embodiment, the extending direction of the first connection area CA1 may be changed from the second direction (e.g., the y-direction or the −y-direction) to the first direction (e.g., the x-direction or the −x-direction), for example. In another embodiment, the extending direction of the first connection area CA1 may be changed from the first direction (e.g., the x-direction or the −x-direction) to the second direction (e.g., the y-direction or the −y-direction). Although FIG. 6 illustrates that an edge of the first connection area CA1 is bent at a right angle, in another embodiment, the edge of the first connection area CA1 may be bent at various angles. In another embodiment, the edge of the first connection area CA1 may be curved.

The opening area OPA may be between adjacent pixel areas PA. In an embodiment, the first opening area OPA1 may be between the first pixel area PA1 and the second pixel area PA2. In a plan view, at least a portion of the first opening area OPA1 may be defined as an edge PAE1 of the first pixel area PA1, an edge PAE2 of the second pixel area PA2, and an edge CAE1 of the first connection area CA1.

FIG. 6 shows four pixel areas PA and first connection areas CA1 extended to the four pixel areas PA, and the four pixel areas PA and the first connection areas CA1 extended to the four pixel areas PA may be defined as a first basic unit. The first basic unit may be repeated in the first direction (e.g., the x-direction or the −x-direction) and/or the second direction (e.g., the y-direction or the −y-direction) in the display area DA.

The non-display area NDA may include a driving circuit area DCA, a wire area WLA and a second connection area CA2, and an opening area OPA may be defined in the non-display area NDA. The driving circuit area DCA and the wire area WLA may be a base area included in the non-display area NDA. In an embodiment, the driving circuit area DCA and the wire area WLA may be adjacent to each other in the first direction (e.g., the x-direction or the −x-direction). Each of the driving circuit area DCA and the wire area WLA may be provided in plural. The plurality of driving circuit areas DCA may be arranged in the first direction (e.g., the x-direction or the −x-direction) and/or the second direction (e.g., the y-direction or the −y-direction). In an embodiment, the driving circuit area DCA may include a first driving circuit area DCA1 and a second driving circuit area DCA2. The first driving circuit area DCA1 and the second driving circuit area DCA2 may be adjacent to each other. In an embodiment, the plurality of driving circuit areas DCA may be arranged in the second direction (e.g., the y direction or the −y direction). The plurality of wire areas WLA may be arranged in the second direction (e.g., the y direction or the −y direction).

The second connection area CA2 may be a second bridge area in the non-display area NDA. In the non-display area NDA, adjacent base areas may be extended to each other by the second connection area CA2. The second connection area CA2 may extend from the driving circuit area DCA or the wire area WLA to the adjacent driving circuit area DCA or the adjacent wire area WLA. One driving circuit area DCA may be extended to four second connection areas CA2. The four second connection areas CA2 may extend from respective vertices of one driving circuit area DCA. Each of the four second connection areas CA2 may be extended to the adjacent driving circuit area DCA or the adjacent wire area WLA. One wire area WLA may be extended to four second connection areas CA2. The four second connection areas CA2 may extend from respective vertices of one wire area WLA. Each of the four second connection areas CA2 may be extended to the adjacent driving circuit area DCA or the adjacent wire area WLA.

An extending direction of the second connection area CA2 may be changed. In an embodiment, the extending direction of the second connection area CA2 may be changed from the second direction (e.g., the y-direction or the −y-direction) to the first direction (e.g., the x-direction or the −x-direction). In another embodiment, the extending direction of the second connection area CA2 may be changed from the first direction (e.g., the x-direction or the −x-direction) to the second direction (e.g., the y-direction or the −y-direction). Although FIG. 6 illustrates that an edge of the second connection area CA2 is bent at a right angle, in another embodiment, the edge of the second connection area CA2 may be bent at various angles. In another embodiment, the edge of the second connection area CA2 may be curved.

The shape of a portion of the connection area CA extended to the first driving circuit area DCA1 and the shape of a portion of the connection area CA extended to the second driving circuit area DCA2 may be inverted to each other based on a first virtual straight line STL1 passing through a center DCAC1 of the first driving circuit area DCA1 and a center DCAC2 of the second driving circuit area DCA2. In an embodiment, the shape of a portion of the connection area CA extended from the right side of the first driving circuit area DCA1 and the shape of a portion of the connection area CA extended from the left side of the second driving circuit area DCA2 may be inverted from each other based on the first virtual straight line STL1, for example.

The opening area OPA may be between the driving circuit area DCA and the wire area WLA. In an alternative embodiment, the opening area OPA may be between the adjacent driving circuit areas DCA. In an alternative embodiment, the opening area OPA may be between the adjacent wire areas WLA. In an embodiment, the second opening area OPA2 may be between the first driving circuit area DCA1 and the second driving circuit area DCA2. In a plan view, at least a portion of the second opening area OPA2 may be defined as an edge DCAE1 of the first driving circuit area DCA1, an edge DCAE2 of the second driving circuit area DCA2, and an edge CAE2 of the second connection area CA2.

In a plan view, shapes of the plurality of base areas may be the same. In a plan view, a shape of the driving circuit area DCA, a shape of the wire area WLA, and a shape of the pixel area PA may be the same as each other. In a plan view, a width DCAw1 of the first driving circuit area DCA1 and a width DCAw2 of the second driving circuit area DCA2 may be the same as each other. In a plan view, the width DCAw1 of the first driving circuit area DCA1 may be a distance between edges of the first driving circuit area DCA1 opposite to each other in the first direction (e.g., the x direction or the −x direction). In a plan view, a width DCAw2 of the second driving circuit area DCA2 may be a distance between edges of the second driving circuit area DCA2 opposite to each other in the first direction (e.g., the x direction or the −x direction). In a plan view, the width DCAw1 of the first driving circuit area DCA1 may be the same as a width WLAw of the wire area WLA. In a plan view, the width WLAw of the wire area WLA may be a distance between edges of the wire area WLA opposite to each other in the first direction (e.g., the x direction or the −x direction).

In a plan view, a width PAw1 of the first pixel area PA1, a width PAw2 of the second pixel area PA2, the width DCAw1 of the first driving circuit area DCA1, and the width DCAw2 of the second driving circuit area DCA2 may be the same as each other. In a plan view, the width PAw1 of the first pixel area PA1 may be a distance between edges of the first pixel area PA1 opposite to each other in the first direction (e.g., the x direction or the −x direction). In a plan view, the width PAw2 of the second pixel area PA2 may be a distance between edges of the second pixel area PA2 opposite to each other in the first direction (e.g., the x direction or the −x direction). In an embodiment, in a plan view, the width PAw1 of the first pixel area PA1, the width PAw2 of the second pixel area PA2, the width DCAw1 of the first driving circuit area DCA1, the width DCAw2 of the second driving circuit area DCA2, and the width WLAw of the wire area WLA may be the same as each other.

Shapes of the plurality of connection areas CA may be the same as each other. The shape of the first connection area CA1 may be the same as the shape of the second connection area CA2. A width CAw1 of the first connection area CA1 may be the same as a width CAw2 of the second connection area CA2. In an embodiment, the width CAw1 of the first connection area CA1 may be a distance between edges of the first connection area CA1 opposite to each other in the first direction (e.g., the x direction or the −x direction). In an embodiment, the width CAw2 of the second connection area CA2 may be a distance between edges of the second connection area CA2 opposite to each other in the first direction (e.g., the x direction or the −x direction). Accordingly, the shape of the substrate 100 in the display area DA may be the same as the shape of the substrate 100 in the non-display area NDA. Unlike the illustrated embodiment, when the shape of the substrate 100 in the display area DA is different from the shape of the substrate 100 in the non-display area NDA, when an external force is applied, stress may concentrate at the boundary between the display area DA and the non-display area NDA. In this case, the display device 1 may be damaged at the boundary between the display area DA and the non-display area NDA. In the illustrated embodiment, because the shape of the substrate 100 in the display area DA is the same as the shape of the substrate 100 in the non-display area NDA, a phenomenon in which stress concentrates at the boundary between the display area DA and the non-display area NDA may be prevented or reduced.

A circuit layer may be on the substrate 100. The circuit layer may include a first pixel circuit PC1, a second pixel circuit PC2, a first driving circuit DC1, a second driving circuit DC2, and a wire WL. The first pixel circuit PC1 may overlap the first pixel area PA1. The second pixel circuit PC2 may overlap the second pixel area PA2.

The first driving circuit DC1 may overlap the first driving circuit area DCA1. The first driving circuit DC1 may generate and output a signal to be applied to a pixel circuit arranged in the same row. The first driving circuit DC1 may include a first conductive pattern CP1. In an embodiment, the first conductive pattern CP1 may be an electrode constituting the first driving circuit DC1. In an embodiment, the first conductive pattern CP1 may be a semiconductor layer constituting the first driving circuit DC1. The shape of the first conductive pattern CP1 may include a polygonal shape, such as a triangle or a quadrangle, or a curved shape.

The second driving circuit DC2 may overlap the second driving circuit area DCA2. The second driving circuit DC2 may generate and output a signal to be applied to a pixel circuit arranged in the same row. The second driving circuit DC2 may include a second conductive pattern CP2. In an embodiment, the second conductive pattern CP2 may be an electrode constituting the second driving circuit DC2. In an embodiment, the second conductive pattern CP2 may be a semiconductor layer constituting the second driving circuit DC2. The shape of the second conductive pattern CP2 may include a polygonal shape, such as a triangle or a quadrangle, or a curved shape.

The shape of the first conductive pattern CP1 and the shape of the second conductive pattern CP2 may be inverted from each other based on the first virtual straight line STL1 passing through the center DCAC1 of the first driving circuit area DCA1 and the center DCAC2 of the second driving circuit area DCA2 in a plan view. In an embodiment, the first virtual straight line STL1 may extend in the second direction (e.g., the y direction or the −y direction). In other words, the shape of the first driving circuit DC1 and the shape of the second driving circuit DC2 adjacent in the second direction (e.g., the y direction or the −y direction) may be inverted from each other based on the first virtual straight line STL1. Accordingly, driving circuits may be arranged in a base area according to the shape of the substrate 100 in the non-display area NDA, and thus, the display device 1 may have a high elongation.

The wire WL may include a first wire WL1 and a second wire WL2. The first wire WL1 may be electrically connected to the first driving circuit DC1. The first wire WL1 may extend from the first driving circuit DC1. In an embodiment, the first wire WL1 may extend from the first driving circuit area DCA1 to the connection area CA, for example.

The second wire WL2 may be electrically connected to the second driving circuit DC2. The second wire WL2 may extend from the second driving circuit DC2. In an embodiment, the second wire WL2 may extend from the second driving circuit area DCA2 to the connection area CA, for example.

The shape of the first wire WL1 in the first driving circuit area DCA1 and the shape of the second wire WL2 in the second driving circuit area DCA2 may be inverted from each other based on the first virtual straight line STL1 passing through the center DCAC1 of the first driving circuit area DCA1 and the center DCAC2 of the second driving circuit area DCA2 in a plan view. Wirings may be arranged in a base area according to the shape of the substrate 100 in the non-display area NDA, and thus, the display device 1 may have a high elongation.

The wire WL may extend from the wire area WLA to the driving circuit area DCA, the wire area WLA, or the pixel area PA through the connection area CA. The wire WL may be electrically connected to a driving circuit. In an embodiment, the wire WL may be a signal line transmitting an external signal or a previous signal. In another embodiment, the wire WL may be a clock signal line that transmits a clock signal for driving the driving circuit. In another embodiment, the wire WL may be a power line that transmits a rated voltage for driving the driving circuit. In another embodiment, the wire WL may be a signal line that transmits a signal output from the driving circuit to a pixel circuit. Accordingly, the pixel circuit arranged in the same row as the driving circuit by the wire WL may receive a signal. In another embodiment, the wire WL may be a carry signal line that transmits a carry signal output from the first driving circuit DC1 to the second driving circuit DC2.

As such, the types of wires WL connected to the driving circuit may vary. When the wire area WLA is omitted, various wires WL may be integrated in the connection area CA extended to the driving circuit area DCA. In this case, a width of the connection area CA may be increased, and the display device 1 may not be flexible in the non-display area NDA. In the illustrated embodiment, the non-display area NDA may include the driving circuit area DCA and the wire area WLA, and various wires WL electrically connected to the driving circuit may be distributed. Accordingly, the width of the connection area CA may be kept thin and the non-display area NDA may have a high elongation.

A light-emitting device layer may be on the circuit layer. The light-emitting device layer may include a light-emitting device. In an embodiment, the light-emitting device layer may include a first light-emitting device LE1 and a second light-emitting device LE2. The first light-emitting device LE1 may overlap the first pixel area PA1. The first light-emitting device LE1 may be electrically connected to the first pixel circuit PC1. The second light-emitting device LE2 may overlap the second pixel area PA2. The second light-emitting device LE2 may be electrically connected to the second pixel circuit PC2.

In an embodiment, the first light-emitting device LE1 and/or the second light-emitting device LE2 may include a red light-emitting device LEr, a green light-emitting device LEg, and a blue light-emitting device LEb. The red light-emitting device LEr, the green light-emitting device LEg, and the blue light-emitting device LEb may emit red light, green light, and blue light, respectively. In another embodiment, the first light-emitting device LE1 and/or the second light-emitting device LE2 may include the red light-emitting device LEr, the green light-emitting device LEg, the blue light-emitting device LEb, and a white light-emitting device.

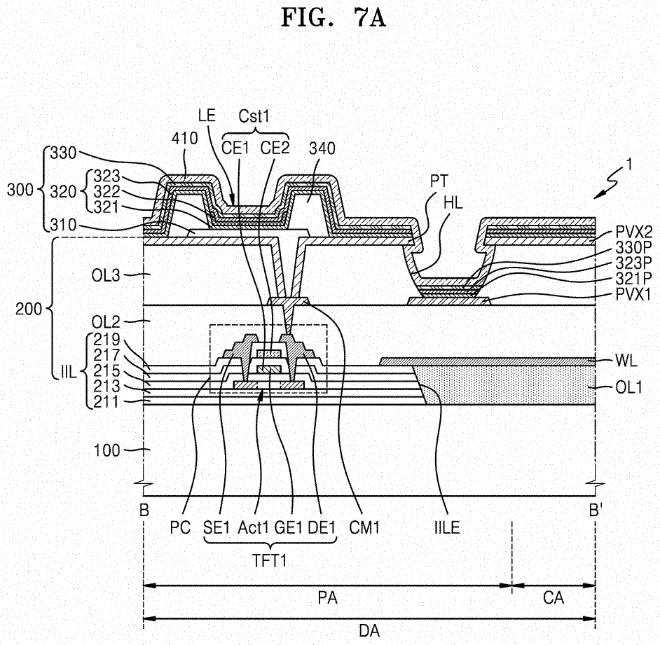

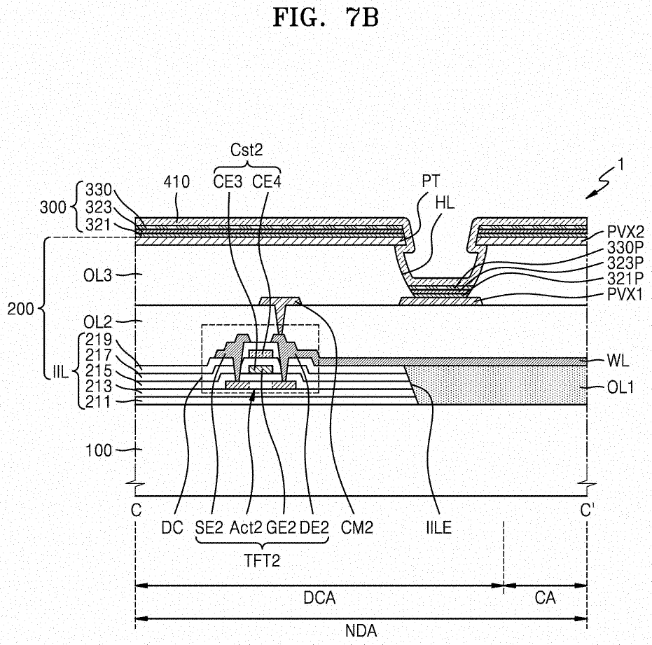

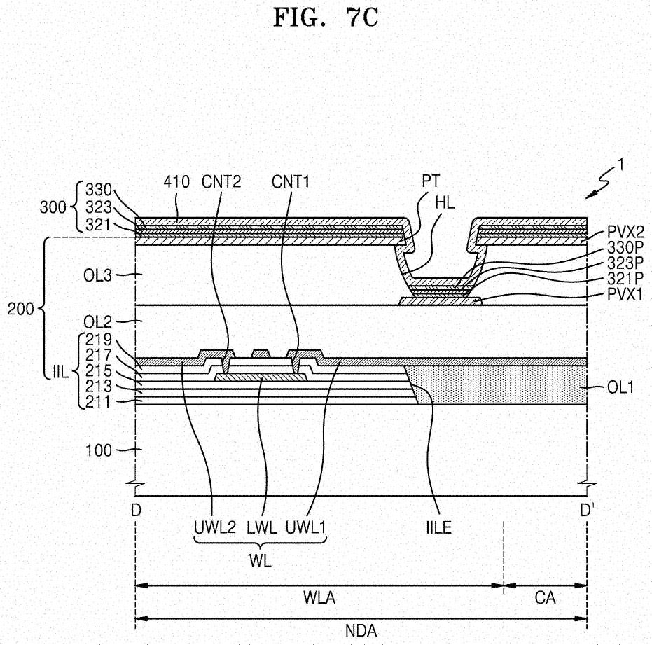

FIG. 7A is a cross-sectional view schematically illustrating the display device 1 of FIG. 6 taken along line B-B′.

Referring to FIG. 7A, the display device 1 may include the substrate 100, a circuit layer 200, a light-emitting device layer 300, and an inorganic encapsulation layer 410. The substrate 100 may include the display area DA and the non-display area. The display area DA may include the pixel area PA and the connection area CA. The substrate 100 may include a polymer resin such as polyethersulfone, polyarylate, polyetherimide, polyethylene naphthalate, polyethylene terephthalate, polyphenylene sulfide, polyimide, polycarbonate, cellulose triacetate, cellulose acetate propionate, or the like. In an embodiment, the substrate 100 may have a multilayer structure including a base layer and a barrier layer (not shown) including the above-described polymer resin. The substrate 100 including the polymer resin may be flexible, rollable, and bendable. In some embodiments, the substrate 100 may include glass.

The circuit layer 200 may be on the substrate 100. The circuit layer 200 may include the pixel circuit PC, the wire WL, an inorganic insulating layer IIL, a first planarization layer OL1, a second planarization layer OL2, a first contact electrode CM1, a third planarization layer OL3, a first inorganic layer PVX1, and a second inorganic layer PVX2. The pixel circuit PC may include a first transistor TFT1 and a first storage capacitor Cst1. The first transistor TFT1 may include a first semiconductor layer Act1, a first gate electrode GE1, a first source electrode SE1, and a first drain electrode DE1. The first storage capacitor Cst1 may include a first capacitor electrode CE1 and a second capacitor electrode CE2. However, the invention is not limited thereto, and in another embodiment, a drain electrode (e.g., first drain electrode DE1) of a transistor (e.g., first transistor TFT1) may be a source electrode (e.g., a first source electrode SE1) according to a type of the transistor.

The inorganic insulating layer IIL may be on the substrate 100. The inorganic insulating layer IIL may include a barrier layer 211, a buffer layer 213, a first gate insulating layer 215, a second gate insulating layer 217, and an inter-insulating layer 219.

The barrier layer 211 may be on the substrate 100. The barrier layer 211 may be a layer that prevents or reduces penetration of foreign substances. The barrier layer 211 may be a single layer or multiple layers including an inorganic material such as SiNₓ, SiO₂, and/or SiON.

The buffer layer 213 may be on the barrier layer 211. The buffer layer 213 may include an inorganic insulating material such as SiNₓ, SiON, and/or SiO₂, and may be a single layer or multiple layers including the above-described inorganic insulating material.

The first semiconductor layer Act1 may be on the buffer layer 213. The first semiconductor layer Act1 may include polysilicon. In an alternative embodiment, the first semiconductor layer Act1 may include amorphous silicon, an oxide semiconductor, or an organic semiconductor. In an embodiment, the first semiconductor layer Act1 may include a channel area and a source area and a drain area respectively disposed on opposite sides of the channel area.

The first gate insulating layer 215 may be on the first semiconductor layer Act1 and the buffer layer 213. The first gate insulating layer 215 may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂) or zinc oxide (ZnOₓ). ZnOₓ may include zinc oxide (ZnO) and/or zinc peroxide (ZnO₂).

The first gate electrode GE1 may be on the first gate insulating layer 215. The first gate electrode GE1 may overlap the channel area of the first semiconductor layer Act1. The first gate electrode GE1 may include a low-resistance metal material. In an embodiment, the first gate electrode GE1 may include a conductive material including molybdenum (Mo), aluminum (Al), copper (Cu), titanium (Ti), or the like, and may be formed or provided as a single layer or multiple layers including the materials described above.

The second gate insulating layer 217 may be on the first gate electrode GE1 and the first gate insulating layer 215. The second gate insulating layer 217 may include an inorganic insulating material such as SiO₂, SiNₓ, SiON, Al₂O₃, TiO₂, Ta₂O₅, HfO₂, or ZnOₓ.

The second capacitor electrode CE2 may be on the second gate insulating layer 217. The second capacitor electrode CE2 may overlap the first gate electrode GE1. In this case, the first gate electrode GE1 may function as the first capacitor electrode CE1. FIG. 7A illustrates that the first storage capacitor Cst1 and the first transistor TFT1 overlap each other, but in another embodiment, the first storage capacitor Cst1 and the first transistor TFT1 may not overlap each other. In this case, the first capacitor electrode CE1 and the first gate electrode GE1 may be separate electrodes. The second capacitor electrode CE2 may include Al, Pt, Pd, Ag, Mg, Au, Ni, Nd, Ir, Cr, Ca, Mo, Ti, W and/or Cu, and may be a single layer or multiple layers of the above-described materials.

The inter-insulating layer 219 may be on the second capacitor electrode CE2 and the second gate insulating layer 217. The inter-insulating layer 219 may include an inorganic insulating material such as SiO₂, SiNₓ, SiON, Al₂O₃, TiO₂, Ta₂O₅, HfO₂, or ZnOₓ.

Each of the first source electrode SE1 and the first drain electrode DE1 may be on the inter-insulating layer 219. Each of the first source electrode SE1 and the first drain electrode DE1 may be connected to the first semiconductor layer Act1 through a contact hole provided in the first gate insulating layer 215, the second gate insulating layer 217, and the inter-insulating layer 219. At least one of the first source electrode SE1 and the first drain electrode DE1 may include a conductive material including Mo, Al, Cu, Ti, or the like, and may include a single layer or multiple layers including the above-described materials. In an embodiment, at least one of the first source electrode SE1 and the first drain electrode DE1 may have a Ti/Al/Ti multilayer structure.

In an embodiment, the inorganic insulating layer IIL in the display area DA may overlap the pixel area PA and not overlap the connection area CA. The inorganic insulating layer IIL may have an end IILE of the inorganic insulating layer IIL facing the connection area CA. Accordingly, the display device 1 may be flexible in the connection area CA. In FIG. 7A, the end IILE of the inorganic insulating layer IIL does not have a step difference, but in another embodiment, the end IILE of the inorganic insulating layer IIL may have a step difference. In some embodiments, the inorganic insulating layer IIL may be continuously arranged in the pixel area PA and the connection area CA. Hereinafter, a case where the inorganic insulating layer IIL has the end IILE will be described in detail.

The first planarization layer OL1 may overlap the connection area CA. The first planarization layer OL1 may cover the end IILE of the inorganic insulating layer IIL. When the wire WL extends from the pixel area PA to the connection area CA, the first planarization layer OL1 may minimize a height difference or simultaneously absorb stress that may be applied to the wire WL. The first planarization layer OL1 may include an organic material. The first planarization layer OL1 may include an organic insulating material such as a general commercial polymer such as polymethyl methacrylate (“PMMA”) or polystyrene (“PS”), a polymer derivative including a phenolic group, an acrylic polymer, an imide polymer, an aryl ether polymer, an amide polymer, a fluorine-based polymer, a p-xylene-based polymer, a vinyl alcohol polymer, and any combinations thereof.

The wire WL may be on the inorganic insulating layer IIL and the first planarization layer OL1. The wire WL may extend from the pixel area PA to the connection area CA. Although not shown, the wire WL may be electrically connected to the pixel circuit PC. The wire WL may include a conductive material including Mo, Al, Cu, or Ti, and may be provided as a single layer or multiple layers including the above-described materials. In an embodiment, the wire WL may have a multilayer structure of Ti/Al/Ti.

The second planarization layer OL2 may be on the inorganic insulating layer IIL, the first source electrode SE1, the first drain electrode DE1, and the wire WL. The second planarization layer OL2 may include an organic material. The second planarization layer OL2 may include an organic insulating material such as a general commercial polymer such as PMMA or PS, a polymer derivative including a phenolic group, an acrylic polymer, an imide polymer, an aryl ether polymer, an amide polymer, a fluorine-based polymer, a p-xylene-based polymer, a vinyl alcohol polymer, and any combinations thereof.

The wire WL may be between the first planarization layer OL1 and the second planarization layer OL2 in the connection area CA. When the shape of the display device 1 is deformed, the connection area CA may be bent. In this case, a stress neutral plane may exist in the display device 1. When the wire WL is not arranged between the first planarization layer OL1 and the second planarization layer OL2, excessive stress may be applied to the wire WL. In the illustrated embodiment, the wire WL is between the first planarization layer OL1 and the second planarization layer OL2 and thus may be on a stress neutral plane. Accordingly, the stress applied to the wire WL may be minimized.

The first contact electrode CM1 may overlap the pixel area PA and may be on the second planarization layer OL2. The first contact electrode CM1 may be electrically connected to the pixel circuit PC through a contact hole of the second planarization layer OL2. The first contact electrode CM1 may include a conductive material including Mo, Al, Cu, or Ti, and may be provided as a single layer or multiple layers including the above-described materials. The first contact electrode CM1 may have a multilayer structure of Ti/Al/Ti.

The third planarization layer OL3 may be on the second planarization layer OL2 and the first contact electrode CM1. The third planarization layer OL3 may include an organic material. The third planarization layer OL3 may include an organic insulating material such as a general commercial polymer such as PMMA or PS, a polymer derivative including a phenolic group, an acrylic polymer, an imide polymer, an aryl ether polymer, an amide polymer, a fluorine-based polymer, a p-xylene-based polymer, a vinyl alcohol polymer, and any combinations thereof.

In an embodiment, an additional wire may not be between the second planarization layer OL2 and the third planarization layer OL3 in the connection area CA. In the illustrated embodiment, a stress neutral plane may be disposed between the first planarization layer OL1 and the second planarization layer OL2 so that excessive stress is not applied to the wire WL. When an additional wire is between the second planarization layer OL2 and the third planarization layer OL3, the additional wire may not be disposed on the stress neutral plane, and excessive stress may be applied thereto. Accordingly, an additional wire may not be arranged between the second planarization layer OL2 and the third planarization layer OL3, and the reliability of the display device 1 may be increased.

The first inorganic layer PVX1 may be between the second planarization layer OL2 and the third planarization layer OL3. The first inorganic layer PVX1 may include an inorganic material.

A hole HL may be defined in the third planarization layer OL3. The hole HL may expose the first inorganic layer PVX1. The hole HL may be defined by etching the third planarization layer OL3, and the first inorganic layer PVX1 may prevent or reduce over-etching of a component disposed under the first inorganic layer PVX1.

The second inorganic layer PVX2 may be on the third planarization layer OL3. The second inorganic layer PVX2 may have a protruding tip PT protruding from the edge of the hole HL. A lower surface of the protruding tip PT of the second inorganic layer PVX2 may be exposed through the hole HL.

The light-emitting device layer 300 may be on the circuit layer 200. The light-emitting device layer 300 may include the light-emitting device LE and a pixel-defining layer 340. The light-emitting device LE may be an organic light-emitting diode. The light-emitting device LE may include a pixel electrode 310, an intermediate layer 320, and an opposite electrode 330.

The pixel electrode 310 may be electrically connected to the first contact electrode CM1 through a contact hole of the third planarization layer OL3. Accordingly, the light-emitting device LE may be electrically connected to the pixel circuit PC. The pixel electrode 310 may include a conductive oxide such as indium tin oxide (“ITO”), indium zinc oxide (“IZO”), ZnO, indium oxide (In2O3), indium gallium oxide (“IGO”), and/or aluminum zinc oxide (“AZO”). In another embodiment, the pixel electrode 310 may include a reflective layer including Ag, Mg, Al, Pt, Pd, Au, Ni, Nd, Ir, Cr, or any combinations thereof. In another embodiment, the pixel electrode 310 may further include a film including ITO, IZO, ZnO, or In₂O₃ above/below the reflective layer described above.

The pixel-defining layer 340 may cover an edge of the pixel electrode 310. A pixel opening may be defined in the pixel-defining layer 340, and the pixel opening may overlap the pixel electrode 310. The pixel opening may define a light-emitting area of light emitted from the light-emitting device LE. The pixel-defining layer 340 may include an organic insulating material and/or an inorganic insulating material. In some embodiments, the pixel-defining layer 340 may include a light-blocking material.

The intermediate layer 320 may be on the pixel electrode 310, the pixel-defining layer 340, and/or the second inorganic layer PVX2. The intermediate layer 320 may include an emission layer 322. The emission layer 322 may overlap the pixel electrode 310. The emission layer 322 may include a high-molecular weight organic material or a low-molecular weight organic material that emits light of a predetermined color.

The intermediate layer 320 may further include at least one of a first functional layer 321 and a second functional layer 323. The first functional layer 321 may be between the pixel electrode 310 and the emission layer 322. The first functional layer 321 may include a hole transport layer (“HTL”) and/or a hole injection layer (“HIL”). The second functional layer 323 may be between the emission layer 322 and the opposite electrode 330. The second functional layer 323 may include an electron transport layer (“ETL”) and/or an electron injection layer (“EIL”). In an embodiment, the first functional layer 321 and the second functional layer 323 may be disposed on an entirety of the pixel area PA and the connection area CA.

The opposite electrode 330 may be on the pixel electrode 310, the intermediate layer 320, and the pixel-defining layer 340. The opposite electrode 330 may include a conductive material having a low work function. In an embodiment, the opposite electrode 330 may include a (semi) transparent layer including Ag, Mg, Al, Pt, Pd, Au, Ni, Nd, Ir, Cr, lithium (Li), calcium (Ca), or an alloy thereof, for example. In an alternative embodiment, the opposite electrode 330 may further include a layer such as ITO, IZO, ZnO, or In₂O₃ on the (semi) transparent layer including the above-mentioned material.

The protruding tip PT may be a component for increasing the reliability of the display device 1. At least one of the first functional layer 321 and the second functional layer 323 may include an organic material, and external oxygen or moisture may flow into the light-emitting device LE through at least one of the first functional layer 321 and the second functional layer 323. Such oxygen or moisture may damage the light-emitting device LE. In the illustrated embodiment, because the second inorganic layer PVX2 has the protruding tip PT protruding from the edge of the hole HL, the first functional layer 321 and the second functional layer 323 may be respectively cut off based on the hole HL. Accordingly, Inflow of moisture or oxygen into the light-emitting device LE from the outside may be prevented or reduced. Accordingly, the reliability of the display device 1 may be increased.

In an embodiment, at least one of a first functional layer pattern 321P including the same material as that of the first functional layer 321 and a second functional layer pattern 323P including the same material as that of the second functional layer 323 may be arranged inside the hole HL. In an embodiment, an opposite electrode pattern 330P including the same material as that of the opposite electrode 330 may be on the first functional layer pattern 321P and/or the second functional layer pattern 323P.

The inorganic encapsulation layer 410 may be on the light-emitting device layer 300. The inorganic encapsulation layer 410 may be continuously disposed on an entirety of the first pixel area PA1 and the first connection area CA1. The inorganic encapsulation layer 410 may directly contact a lower surface of the protruding tip PT of the second inorganic layer PVX2. Accordingly, inflow of moisture or oxygen into the light-emitting device LE from the outside may be prevented or reduced.

In some embodiments, the organic encapsulation layer may be on the inorganic encapsulation layer 410 to overlap the light-emitting device LE. In addition, an additional inorganic encapsulation layer may be further disposed on the organic encapsulation layer.

Although not shown, a touch sensor layer and an optical functional layer may be further disposed on the inorganic encapsulation layer 410. The touch sensor layer may be on the inorganic encapsulation layer 410. The touch sensor layer may sense coordinate information according to an external input, e.g., a touch event. The touch sensor layer may include a sensor electrode and touch wires connected to the sensor electrode. The touch sensor layer may sense an external input using a self-capacitance method or a mutual capacitance method.

The optical functional layer may be on the touch sensor layer. The optical functional layer may reduce the reflectance of light (e.g., external light) incident toward the display device 1 from the outside. The optical functional layer may improve color purity of light emitted from the display device 1. In an embodiment, the optical functional layer may include a retarder and a polarizer. The retarder may be of a film type or a liquid crystal coating type, and may include a A/2 retarder and/or a A/4 retarder. However, the invention is not limited thereto, and the retarder may include various other retarders. The polarizer may also be of a film type or a liquid crystal coating type. The film type may include a stretch-type synthetic resin film, and the liquid crystal coating type may include liquid crystals arranged in a predetermined arrangement. The retarder and the polarizer may further include a protective film.

In another embodiment, the optical functional layer may include a black matrix and color filters. The color filters may be arranged considering the color of light emitted from each of pixels of the display device 1. Each of the color filters may include a red, green, or blue pigment or dye. In an alternative embodiment, each of the color filters may further include a quantum dot in addition to the aforementioned pigment or dye. In an alternative embodiment, some of the color filters may not include the aforementioned pigment or dye and may include scattering particles such as titanium oxide.

In another embodiment, the optical functional layer may include a destructive interference structure. The destructive interference structure may include a first reflective layer and a second reflective layer on respective layers. First reflected light and second reflected light respectively reflected by the first reflective layer and second reflective layer may destructively interfere, and thus external light reflectance may be reduced.

FIG. 7B is a schematic cross-sectional view of the display device 1 of FIG. 6 taken along line C-C′. In FIG. 7B, the same reference numerals as used in FIG. 7A denote the same elements, and a duplicate description will not be given herein.

Referring to FIG. 7B, the display device 1 may include the substrate 100, the circuit layer 200, the light-emitting device layer 300, and the inorganic encapsulation layer 410. In an embodiment, the substrate 100 may include the display area DA and the non-display area NDA, for example. The non-display area NDA may include the driving circuit area DCA and the connection area CA.

The circuit layer 200 may be on the substrate 100. The circuit layer 200 may include the driving circuit DC, the wire WL, the first planarization layer OL1, the second planarization layer OL2, a second contact electrode CM2, the third planarization layer OL3, the first inorganic layer PVX1, and the second inorganic layer PVX2. The driving circuit DC may overlap the driving circuit area DCA. The driving circuit DC may include a second transistor TFT2 and a second storage capacitor Cst2. The second transistor TFT2 may include a second semiconductor layer Act2, a second gate electrode GE2, a second source electrode SE2, and a second drain electrode DE2. The second storage capacitor Cst2 may include a third capacitor electrode CE3 and a fourth capacitor electrode CE4. In an embodiment, the driving circuit DC may include a conductive pattern, and the conductive pattern may be any one of the second semiconductor layer Act2, the second gate electrode GE2, the second source electrode SE2, the second drain electrode DE2, the third capacitor electrode CE3, and the fourth capacitor electrode CE4.

The inorganic insulating layer IIL may be on the substrate 100. The inorganic insulating layer IIL may include the barrier layer 211, the buffer layer 213, the first gate insulating layer 215, the second gate insulating layer 217, and the inter-insulating layer 219.

The second semiconductor layer Act2 may be between the buffer layer 213 and the first gate insulating layer 215. The second semiconductor layer Act2 may include polysilicon. In an alternative embodiment, the second semiconductor layer Act2 may include amorphous silicon, an oxide semiconductor, or an organic semiconductor. In an embodiment, the second semiconductor layer Act2 may include a channel area and a source area and a drain area respectively disposed on opposite sides of the channel area.

The second gate electrode GE2 may be between the first gate insulating layer 215 and the second gate insulating layer 217. The second gate electrode GE2 may overlap the channel area of the second semiconductor layer Act2. The second gate electrode GE2 may include a low-resistance metal material. In an embodiment, the second gate electrode GE2 may include a conductive material including Mo, Al, Cu, Ti, or the like, and may be formed as a single layer or multiple layers including the materials described above.

The fourth capacitor electrode CE4 may be between the second gate insulating layer 217 and the inter-insulating layer 219. The fourth capacitor electrode CE4 may overlap the second gate electrode GE2. In this case, the second gate electrode GE2 may function as the third capacitor electrode CE3. FIG. 7B illustrates that the second storage capacitor Cst2 and the second transistor TFT2 overlap each other, but in another embodiment, the second storage capacitor Cst2 and the second transistor TFT2 may not overlap each other. In this case, the third capacitor electrode CE3 and the second gate electrode GE2 may be separate electrodes. The fourth capacitor electrode CE4 may include Al, Pt, Pd, Ag, Mg, Au, Ni, Nd, Ir, Cr, Ca, Mo, Ti, W, and/or Cu, and may be a single layer or multiple layers of the above-described materials.

Each of the second source electrode SE2 and the second drain electrode DE2 may be on the inter-insulating layer 219. Each of the second source electrode SE2 and the second drain electrode DE2 may be connected to the second semiconductor layer Act2 through a contact hole provided in the first gate insulating layer 215, the second gate insulating layer 217, and the inter-insulating layer 219. At least one of the second source electrode SE2 and the second drain electrode DE2 may include a conductive material including Mo, Al, Cu, or Ti, and may include a single layer or multiple layers including the above-described materials. In an embodiment, at least one of the second source electrode SE2 and the second drain electrode DE2 may have a Ti/Al/Ti multilayer structure.

In an embodiment, the inorganic insulating layer IIL may overlap the driving circuit area DCA and not overlap the connection area CA. The inorganic insulating layer IIL may have the end IILE of the inorganic insulating layer IIL facing the connection area CA. Accordingly, the display device 1 may be flexible in the connection area CA. In some embodiments, the inorganic insulating layer IIL may be continuously arranged in the pixel area PA and the connection area CA. Hereinafter, a case where the inorganic insulating layer IIL has the end IILE will be described in detail.

The first planarization layer OL1 may overlap the connection area CA. The first planarization layer OL1 may cover the end IILE of the inorganic insulating layer IIL. When the wire WL extends from the driving circuit area DCA to the second connection area CA2, the first planarization layer OL1 may minimize a height difference or simultaneously absorb stress that may be applied to the wire WL.

The wire WL may be on the inorganic insulating layer IIL and the first planarization layer OL1. The wire WL may extend from the driving circuit area DCA to the connection area CA. The wire WL may be electrically connected to the driving circuit DC. In some embodiments, the wire WL may be unitary with the second source electrode SE2 or the second drain electrode DE2. In some embodiments, the wire WL may be electrically connected to the second gate electrode GE2. Because the wire WL is between the first planarization layer OL1 and the second planarization layer OL2 in the second connection area CA2, the wire WL may be disposed on a stress neutral plane. Accordingly, the stress applied to the wire WL may be minimized.

The second contact electrode CM2 may overlap the driving circuit area DCA and may be between the second planarization layer OL2 and the third planarization layer OL3. The second contact electrode CM2 may be electrically connected to the driving circuit DC through the contact hole of the second planarization layer OL2. The second contact electrode CM2 may include a conductive material including Mo, Al, Cu, or Ti, and may be provided as a single layer or multiple layers including the above-described materials. The second contact electrode CM2 may have a multilayer structure of Ti/Al/Ti.

An emission layer may not be arranged in the non-display area NDA. In some embodiments, components of the light-emitting device layer 300 may not be arranged in the non-display area NDA.

FIG. 7C is a schematic cross-sectional view of the display device 1 of FIG. 6 taken along line D-D′. In FIG. 7C, the same reference numerals as used in FIG. 7B denote the same elements, and a duplicate description will not be given herein.

Referring to FIG. 7C, the display device 1 may include the substrate 100, the circuit layer 200, the light-emitting device layer 300, and the inorganic encapsulation layer 410. The substrate 100 may include a display area and the non-display area NDA. The non-display area NDA may include the wire area WLA and the connection area CA.

The circuit layer 200 may be on the substrate 100. The circuit layer 200 may include the wire WL, the first planarization layer OL1, the second planarization layer OL2, a second contact electrode CM2, the third planarization layer OL3, the first inorganic layer PVX1, and the second inorganic layer PVX2. The inorganic insulating layer IIL may be on the substrate 100. The inorganic insulating layer IIL may include the barrier layer 211, the buffer layer 213, the first gate insulating layer 215, the second gate insulating layer 217, and the inter-insulating layer 219.

The wire WL may overlap the wire area WLA. The wire WL may extend from the wire area WLA to the connection area CA. The wire WL may include a lower wire LWL, a first upper wire UWL1, and a second upper wire UWL2.

The lower wire LWL may be between a first inorganic insulating layer and a second inorganic insulating layer. The lower wire LWL may overlap the wire area WLA. In an embodiment, the first inorganic insulating layer may be one of the barrier layer 211, the buffer layer 213, the first gate insulating layer 215, the second gate insulating layer 217, and the inter-insulating layer 219. The second inorganic insulating layer may be one of the barrier layer 211, the buffer layer 213, the first gate insulating layer 215, the second gate insulating layer 217, and the inter-insulating layer 219. In an embodiment, the lower wire LWL may be between the first gate insulating layer 215 and the second gate insulating layer 217, for example. The lower wire LWL may include a low resistance metal material. In an embodiment, the lower wire LWL may include a conductive material including Mo, Al, Cu, Ti, or the like, and may be formed or provided as a single layer or multiple layers including the materials described above. In another embodiment, the lower wire LWL may be between the second gate insulating layer 217 and the inter-insulating layer 219. The lower wire LWL may include Al, Pt, Pd, Ag, Mg, Au, Ni, Nd, Ir, Cr, Ca, Mo, Ti, W and/or Cu, and may be a single layer or multiple layers of the above-described materials. Hereinafter, a case in which the lower wire LWL is between the first gate insulating layer 215 and the second gate insulating layer 217 will be described in detail.

The first upper wire UWL1 may be on the second inorganic insulating layer. In an embodiment, the first upper wire UWL1 may be on the second gate insulating layer 217 or the inter-insulating layer 219, for example. The first upper wire UWL1 may include a conductive material including Mo, Al, Cu, or Ti, and may be provided as a single layer or multiple layers including the above-described materials. In an embodiment, the first upper wire UWL1 may have a multilayer structure of Ti/Al/Ti.

The first upper wire UWL1 may be electrically connected to the lower wire LWL through a first contact hole CNT1 of the second inorganic insulating layer. In an embodiment, the first upper wire UWL1 may be electrically connected to the lower wire LWL through a first contact hole of the second gate insulating layer 217 and a first contact hole of the inter-insulating layer 219, for example.

The second upper wire UWL2 may be on the second inorganic insulating layer. In an embodiment, the second upper wire UWL2 may be on the second gate insulating layer 217 or the inter-insulating layer 219, for example. The second upper wire UWL2 may include a conductive material including Mo, Al, Cu, or Ti, and may be provided as a single layer or multiple layers including the above-described materials. In an embodiment, the second upper wire UWL2 may have a multilayer structure of Ti/Al/Ti.

The second upper wire UWL2 may be electrically connected to the lower wire LWL through a second contact hole CNT2 of the second inorganic insulating layer. In an embodiment, the second upper wire UWL2 may be electrically connected to the lower wire LWL through a second contact hole of the second gate insulating layer 217 and a second contact hole of the inter-insulating layer 219, for example. Accordingly, the plurality of wires WL may cross each other in the wire area WLA, and the plurality of wires WL may be arranged in various ways.

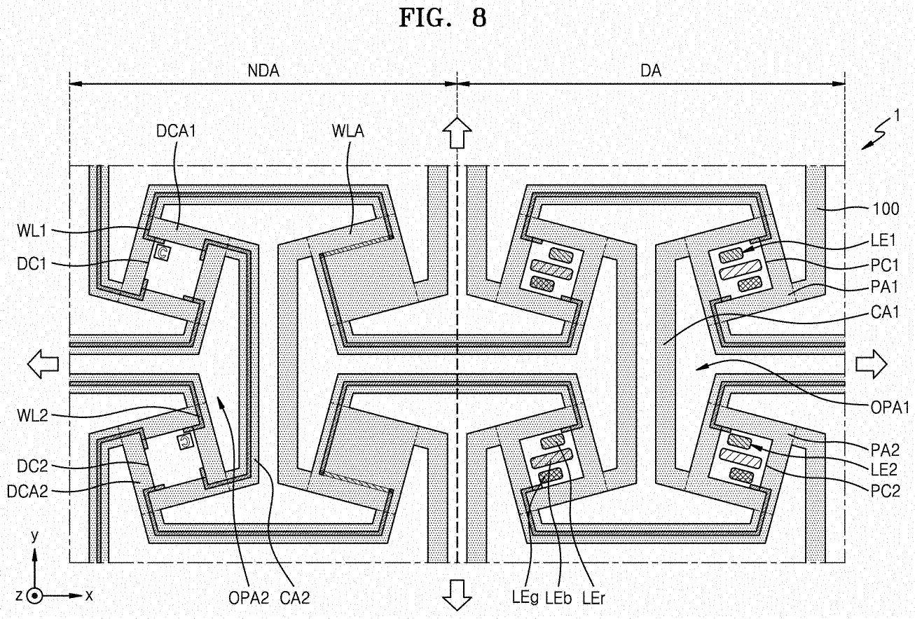

FIG. 8 is a plan view illustrating an embodiment of a deformed state of the display device 1 of FIG. 6 when a tensile force is applied to the display device 1. In FIG. 8, the same reference numerals as used in FIG. 6 denote the same elements, and a duplicate description will not be given herein.

Referring to FIG. 8, a tensile force may be applied to the display device 1 in the first direction (e.g., the x direction or the −x direction) and/or in the second direction (e.g., the y direction or the −y direction). In this case, in the plan view, the first pixel area PA1, the second pixel area PA2, the first driving circuit area DCA1, the second driving circuit area DCA2, and the wire area WLA may rotate, respectively. In an embodiment, each of the first pixel area PA1, the second pixel area PA2, the first driving circuit area DCA1, the second driving circuit area DCA2, and the wire area WLA may rotate in the third direction (e.g., a z direction or a −z direction) as a rotation axis, for example. In this case, the display device 1 may extend in the first direction (e.g., the x direction or the −x direction) and/or the second direction (e.g., the y direction or the −y direction).

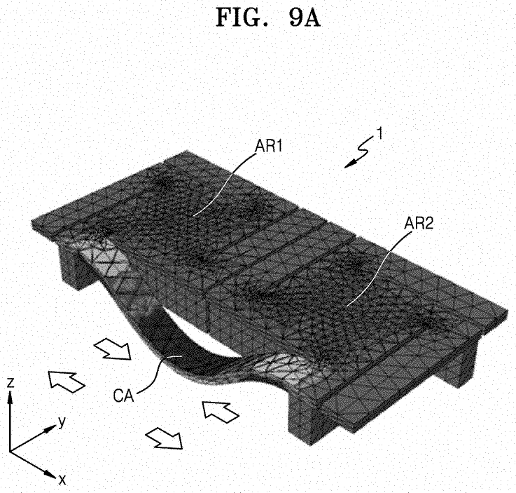

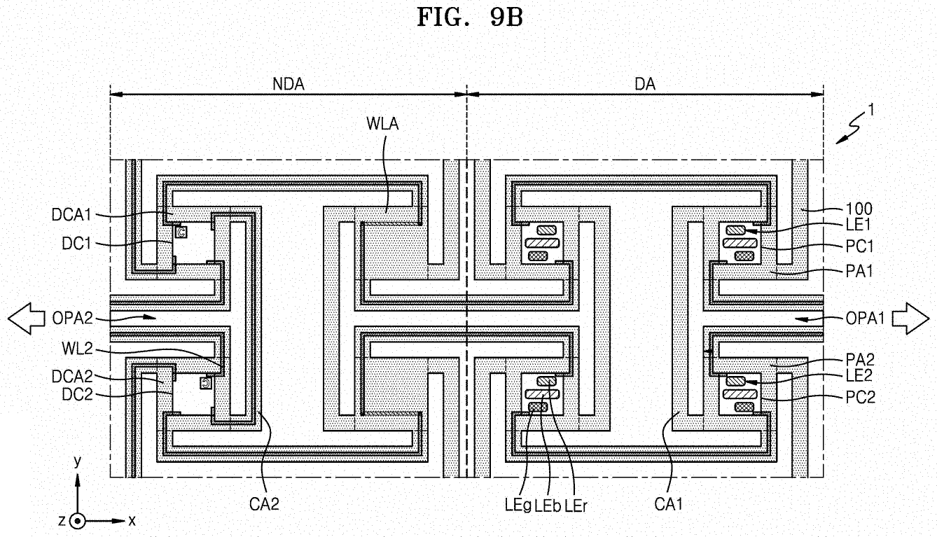

FIG. 9A is a view of another embodiment of a simulation result illustrating a deformed state of the display device 1 of FIG. 6 when a tensile force or a contractile force is applied to the display device 1. FIG. 9B is a plan view illustrating another embodiment of a deformed state of the display device 1 of FIG. 6 when a tensile force is applied to the display device 1.

Referring to FIG. 9A, the display device 1 may include a first area AR1, a second area AR2, and the connection area CA. In an embodiment, the first area AR1 and the second area AR2 may correspond to the first pixel area PA1 and the second pixel area PA2 of FIG. 6, respectively. In another embodiment, the first area AR1 and the second area AR2 may correspond to the first driving circuit area DCA1 and the second driving circuit area DCA2 of FIG. 6, respectively. In another embodiment, the first area AR1 and the second area AR2 may correspond to the driving circuit area DCA and the wire area WLA of FIG. 6, respectively.

When a tensile force or a contractile force is applied to the display device 1, the connection area CA may be bent, and any one portion of the connection area CA may be moved in the third direction (e.g., the z direction or the −z direction). In this case, a distance between the first area AR1 and the second area AR2 may be increased or decreased, and the shape of the display device 1 may be deformed. When the connection area CA is bent as described above, high stretchability of the display device 1 may be secured.

It may be important that a wire arranged in the connection area CA is disposed on a stress neutral plane. In the illustrated embodiment, the wire may be between a first planarization layer and a second planarization layer in which the stress neutral plane is disposed. In addition, because the wire is not arranged between a second planarization layer and a third planarization layer in which the stress neutral plane is not disposed, the reliability of the display device 1 may be high.

Referring to FIG. 9B, a tensile force may be applied to the display device 1 in the first direction (e.g., the x direction or the −x direction). Any one of the first connection area CA1 and/or the second connection area CA2 extending in the first direction (e.g., the x direction or the −x direction) may move in the third direction (e.g., the z direction or the −z direction). In this case, e.g., a distance between the first driving circuit area DCA1 and the wire area WLA may increase, and the shape of the display device 1 may be deformed.

Contrary to the embodiment described with reference to FIG. 9B, a contractile force may be applied to the display device 1 in the first direction (e.g., the x direction or the −x direction). Any one of the first connection area CA1 and/or the second connection area CA2 extending in the first direction (e.g., the x direction or the −x direction) may move in the third direction (e.g., the z direction or the −z direction). In this case, a distance between the first driving circuit area DCA1 and the wire area WLA may decrease, and the shape of the display device 1 may be deformed, for example.

The embodiment described with reference to FIGS. 9A and 9B may have a higher elongation than the embodiment described with reference to FIG. 8. In addition, unlike the embodiment described with reference to FIG. 8, in the embodiment described with reference to FIGS. 9A and 9B, in the display device 1, first stretching in the first direction (e.g., the x direction or the −x direction) and second stretching in the second direction (e.g., the y direction or the −y direction) may be performed independently.

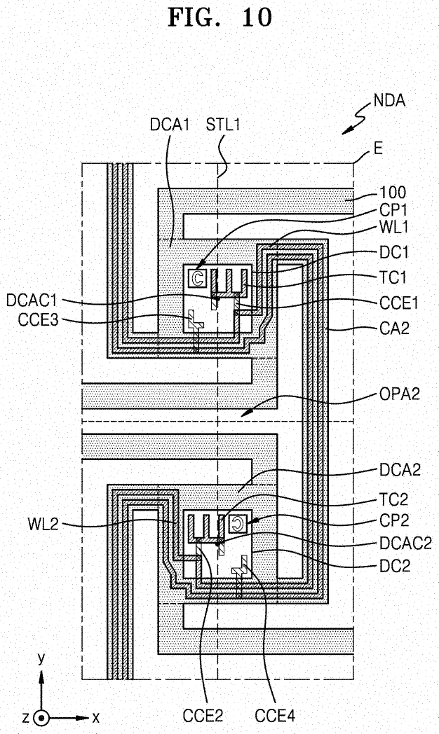

FIG. 10 is a schematic plan view of an embodiment of enlarged portion E of the display device of FIG. 3.

Referring to FIG. 10, the display device may include the substrate 100 and a circuit layer. The substrate 100 may include a display area and the non-display area NDA. The non-display area NDA may include the first driving circuit area DCA1, the second driving circuit area DCA2 and the second connection area CA2, and the second opening area OPA2 may be defined in the non-display area NDA. The first driving circuit area DCA1 and the second driving circuit area DCA2 may be adjacent to each other. The first driving circuit area DCA1 and the second driving circuit area DCA2 may be arranged in the second direction (e.g., the y direction or the −y direction). A connection area may extend from the first driving circuit area DCA1. The first driving circuit area DCA1 may be connected to each of four connection areas CA. The four connection areas CA may extend from respective vertices of the first driving circuit area DCA1. A connection area may extend from the second driving circuit area DCA2. The second driving circuit area DCA2 may be connected to each of four connection areas CA. The four connection areas CA may extend from respective vertices of the second driving circuit area DCA2. The first driving circuit area DCA1 and the second driving circuit area DCA2 may be extended to each other by the second connection area CA2. The second opening area OPA2 may be between the first driving circuit area DCA1 and the second driving circuit area DCA2. In a plan view, at least a portion of the second opening area OPA2 may be defined as an edge of the first driving circuit area DCA1, an edge of the second driving circuit area DCA2, and an edge of the second connection area CA2.

The shape of a portion of the connection area CA extended to the first driving circuit area DCA1 and the shape of a portion of the connection area CA extended to the second driving circuit area DCA2 may be inverted to each other based on the first virtual straight line STL1 passing through the center DCAC1 of the first driving circuit area DCA1 and the center DCAC2 of the second driving circuit area DCA2. In an embodiment, the shape of a portion of the connection area CA extended from the right side of the first driving circuit area DCA1 and the shape of a portion of the connection area CA extended from the left side of the second driving circuit area DCA2 may be inverted from each other based on the first virtual straight line STL1, for example.

A circuit layer may be on the substrate 100. The circuit layer may include the first driving circuit DC1, the second driving circuit DC2, the first wire WL1, the second wire WL2, a first connection electrode CCE1, a second connection electrode CCE2, a third connection electrode CCE3, and a fourth connection electrode CCE4. In an embodiment, each of the first driving circuit DC1 and the second driving circuit DC2 may be a scan driving circuit that generates a scan signal. In another embodiment, each of the first driving circuit DC1 and the second driving circuit DC2 may be an emission control driving circuit that generates an emission control signal.

The first driving circuit DC1 may overlap the first driving circuit area DCA1. The first driving circuit DC1 may include the first conductive pattern CP1. The first conductive pattern CP1 may include a first transistor electrode TC1. The first transistor electrode TC1 may be an electrode included in a transistor included in the first driving circuit DC1.

The second driving circuit DC2 may overlap the second driving circuit area DCA2. The second driving circuit DC2 may include the second conductive pattern CP2. The second conductive pattern CP2 may include a second transistor electrode TC2. The second transistor electrode TC2 may be an electrode included in a transistor included in the second driving circuit DC2.

The shape of the first conductive pattern CP1 and the shape of the second conductive pattern CP2 may be inverted from each other based on the first virtual straight line STL1 passing through the center DCAC1 of the first driving circuit area DCA1 and the center DCAC2 of the second driving circuit area DCA2 in a plan view. In an embodiment, the first virtual straight line STL1 may extend in the second direction (e.g., the y direction or the −y direction). In an embodiment, the shape of the first transistor electrode TC1 and the shape of the second transistor electrode TC2 may be inverted from each other based on the first virtual straight line STL1, for example.

The first conductive pattern CP1 may be on one side with respect to the first virtual straight line STL1, and the second conductive pattern CP2 may be on the other side with respect to the first virtual straight line STL1. In an embodiment, the first conductive pattern CP1 may be on the left side of the first virtual straight line STL1, and the second conductive pattern CP2 may be on the right side of the first virtual straight line STL1, for example. The first transistor electrode TC1 may be deviated to the right with respect to the first virtual straight line STL1, and the second transistor electrode TC2 may be deviated to the left with respect to the first virtual straight line STL1.

The first wire WL1 may be electrically connected to the first driving circuit DC1. The first wire WL1 may extend from the first driving circuit DC1. In an embodiment, the first wire WL1 may extend from the first driving circuit area DCA1 to the second connection area CA2, for example. In an embodiment, the first wire WL1 may extend from the first driving circuit area DCA1 to the second driving circuit area DCA2 through the second connection area CA2. The first wire WL1 may be electrically connected to the second driving circuit DC2.

The second wire WL2 may be electrically connected to the second driving circuit DC2. The second wire WL2 may extend from the second driving circuit DC2. In an embodiment, the second wire WL2 may extend from the second driving circuit area DCA2 to the second connection area CA2. In an embodiment, the second wire WL2 may extend from the second driving circuit area DCA2 to the first driving circuit area DCA1 through the second connection area CA2, for example. The second wire WL2 may be electrically connected to the first driving circuit DC1.

The first wire WL1 and the second wire WL2 may be in the same layer in the second connection area CA2. The first wire WL1 and the second wire WL2 may include the same material. Accordingly, both the first wire WL1 and the second wire WL2 may be disposed on a neutral plane in the second connection area CA2, and the stress applied to the first wire WL1 and the second wire WL2 may be minimized.

The shape of the first wire WL1 in the first driving circuit area DCA1 and the shape of the second wire WL2 in the second driving circuit area DCA2 may be inverted from each other based on the first virtual straight line STL1 passing through the center DCAC1 of the first driving circuit area DCA1 and the center DCAC2 of the second driving circuit area DCA2 in a plan view. A portion of the first wire WL1 arranged in the first driving circuit area DCA1 may be on one side of the first virtual straight line STL1. A portion of the second wire WL2 arranged in the second driving circuit area DCA2 corresponding to a portion of the first wire WL1 may be on the other side of the first virtual straight line STL1.

The first connection electrode CCE1 may overlap the first driving circuit area DCA1. In an embodiment, the first wire WL1 may be electrically connected to the first transistor electrode TC1 by the first connection electrode CCE1. The first connection electrode CCE1 may be in a different layer from that of the first wire WL1 and the first transistor electrode TC1. In an embodiment, the first connection electrode CCE1 may be between a first inorganic insulating layer and a second inorganic insulating layer. The first wire WL1 and the first transistor electrode TC1 may be on the second inorganic insulating layer. The first wire WL1 may be electrically connected to the first connection electrode CCE1 in the first driving circuit area DCA1 through a first contact hole of the second inorganic insulating layer. The first transistor electrode TC1 may be electrically connected to the first connection electrode CCE1 in the first driving circuit area DCA1 through a second contact hole of the second inorganic insulating layer.

The second connection electrode CCE2 may overlap the second driving circuit area DCA2. In an embodiment, the second wire WL2 may be electrically connected to the second transistor electrode TC2 by the second connection electrode CCE2. The second connection electrode CCE2 may be in a different layer from that of the second wire WL2 and the second transistor electrode TC2. In an embodiment, the second connection electrode CCE2 may be between the first inorganic insulating layer and the second inorganic insulating layer. The second wire WL2 and the second transistor electrode TC2 may be on the second inorganic insulating layer. The second wire WL2 may be electrically connected to the second connection electrode CCE2 in the second driving circuit area DCA2 through the first contact hole of the second inorganic insulating layer. The second transistor electrode TC2 may be electrically connected to the second connection electrode CCE2 in the second driving circuit area DCA2 through the second contact hole of the second inorganic insulating layer.

The shape of the first connection electrode CCE1 and the shape of the second connection electrode CCE2 may be inverted from each other based on the first virtual straight line STL1 in a plan view. The first connection electrode CCE1 may be on one side with respect to the first virtual straight line STL1, and the second connection electrode CCE2 may be on the other side with respect to the first virtual straight line STL1. In an embodiment, the first connection electrode CCE1 may be on the right side of the first virtual straight line STL1, and the second connection electrode CCE2 may be on the left side of the first virtual straight line STL1, for example.

The third connection electrode CCE3 may overlap the first driving circuit area DCA1. In an embodiment, the second wire WL2 may be electrically connected to the first driving circuit DC1 by the third connection electrode CCE3. The third connection electrode CCE3 may be in a layer different from that of the second wire WL2. In an embodiment, the third connection electrode CCE3 may be between the first inorganic insulating layer and the second inorganic insulating layer. The second wire WL2 may be on the second inorganic insulating layer. The second wire WL2 may be electrically connected to the third connection electrode CCE3 in the first driving circuit area DCA1 through a third contact hole of the second inorganic insulating layer. In an embodiment, the third connection electrode CCE3 may overlap the first wire WL1.

The fourth connection electrode CCE4 may overlap the second driving circuit area DCA2. In an embodiment, the first wire WL1 may be electrically connected to the second driving circuit DC2 by the fourth connection electrode CCE4. The fourth connection electrode CCE4 may be in a layer different from that of the first wire WL1. In an embodiment, the fourth connection electrode CCE4 may be between the first inorganic insulating layer and the second inorganic insulating layer. The first wire WL1 may be on the second inorganic insulating layer. The first wire WL1 may be electrically connected to the fourth connection electrode CCE4 in the second driving circuit area DCA2 through the third contact hole of the second inorganic insulating layer. In an embodiment, the fourth connection electrode CCE4 may overlap the second wire WL2.

The shape of the third connection electrode CCE3 and the shape of the fourth connection electrode CCE4 may be inverted from each other based on the first virtual straight line STL1 in a plan view. The third connection electrode CCE3 may be on one side with respect to the first virtual straight line STL1, and the fourth connection electrode CCE4 may be on the other side with respect to the first virtual straight line STL1. In an embodiment, the third connection electrode CCE3 may be on the left side of the first virtual straight line STL1, and the fourth connection electrode CCE4 may be on the right side of the first virtual straight line STL1, for example.

In the non-display area NDA, the shape of the display device may be repeated in the second direction (e.g., the y direction or the −y direction). A circuit layer may be arranged in a base area according to the shape of the substrate 100 in the non-display area NDA. Therefore, even when an external force is applied to the display device, stress may not be concentrated in the non-display area NDA, and the non-display area NDA may be transformed into various shapes.

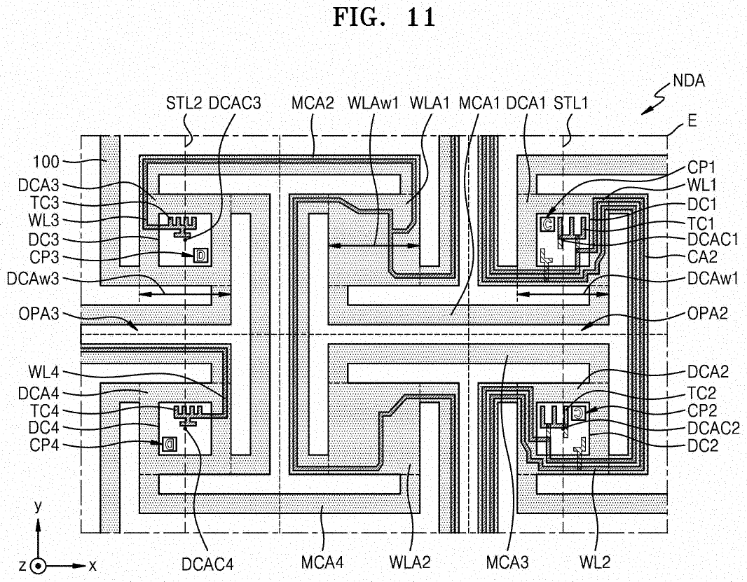

FIG. 11 is an enlarged plan view of another embodiment of portion E of the display device of FIG. 3. In FIG. 11, the same reference numerals as used in FIG. 10 denote the same elements, and a duplicate description will not be given herein.

Referring to FIG. 11, the display device may include the substrate 100 and a circuit layer. In an embodiment, the substrate 100 may include a display area and the non-display area NDA, for example. The non-display area NDA may include the first driving circuit area DCA1, the second driving circuit area DCA2, a third driving circuit area DCA3, a fourth driving circuit area DCA4, a first wire area WLA1, a second wire area WLA2 and a connection area, and the second opening area OPA2 and a third opening area OPA3 may be defined in the non-display area NDA.

The first driving circuit area DCA1 and the second driving circuit area DCA2 may be adjacent to each other. The first driving circuit area DCA1 and the second driving circuit area DCA2 may be arranged in the second direction (e.g., the y direction or the −y direction). The second opening area OPA2 may be between the first driving circuit area DCA1 and the second driving circuit area DCA2. In a plan view, at least a portion of the second opening area OPA2 may be defined as an edge of the first driving circuit area DCA1, an edge of the second driving circuit area DCA2, and an edge of the connection area.

The shape of a portion of the connection area connected to the first driving circuit area DCA1 and the shape of a portion of the connection area connected to the second driving circuit area DCA2 may be inverted to each other based on the first virtual straight line STL1 passing through the center DCAC1 of the first driving circuit area DCA1 and the center DCAC2 of the second driving circuit area DCA2. In an embodiment, the shape of a portion of the connection area connected from the right side of the first driving circuit area DCA1 and the shape of a portion of the connection area connected from the left side of the second driving circuit area DCA2 may be inverted from each other based on the first virtual straight line STL1, for example.

The third driving circuit area DCA3 may be arranged in the first direction (e.g., the x direction or the −x direction) with the first driving circuit area DCA1. The fourth driving circuit area DCA4 may be arranged in the first direction (e.g., the x direction or the −x direction) with the second driving circuit area DCA2. The fourth driving circuit area DCA4 and the third driving circuit area DCA3 may be adjacent to each other. The third driving circuit area DCA3 and the fourth driving circuit area DCA4 may be arranged in the second direction (e.g., the y direction or the −y direction). The third opening area OPA3 may be between the third driving circuit area DCA3 and the fourth driving circuit area DCA4. In a plan view, at least a portion of the third opening area OPA3 may be defined as an edge of the third driving circuit area DCA3, an edge of the fourth driving circuit area DCA4, and an edge of the connection area.

The shape of a portion of the connection area connected to the third driving circuit area DCA3 and the shape of a portion of the connection area connected to the fourth driving circuit area DCA4 may be inverted to each other based on the second virtual straight line STL2 passing through a center DCAC3 of the third driving circuit area DCA3 and a center DCAC4 of the fourth driving circuit area DCA4. In an embodiment, the shape of a portion of the connection area connected from the right side of the third driving circuit area DCA3 and the shape of a portion of the connection area connected from the left side of the fourth driving circuit area DCA4 may be inverted from each other based on the second virtual straight line STL2, for example.

The first wire area WLA1 may be between the first driving circuit area DCA1 and the third driving circuit area DCA3. The first driving circuit area DCA1, the first wire area WLA1, and the third driving circuit area DCA3 may be arranged in the first direction (e.g., the x direction or the −x direction).

The second wire area WLA2 may be between the second driving circuit area DCA2 and the fourth driving circuit area DCA4. The second driving circuit area DCA2, the second wire area WLA2, and the fourth driving circuit area DCA4 may be arranged in the first direction (e.g., the x direction or the −x direction). The second wire area WLA2 may be adjacent to the first wire area WLA1. The first wire area WLA1 and the second wire area WLA2 may be arranged in the second direction (e.g., the y direction or the −y direction).

In a plan view, the shape of the driving circuit area and the shape of the wire area may be the same. In a plan view, the width DCAw1 of the first driving circuit area DCA1, a width WLAw1 of the first wire area WLA1, and a width DCAw3 of the third driving circuit area DCA3 may be the same. In a plan view, the width DCAw1 of the first driving circuit area DCA1 may be a distance between edges of the first driving circuit area DCA1 opposite to each other in the first direction (e.g., the x direction or the −x direction). In a plan view, width WLAw1 of the first wire area WLA1 may be a distance between edges of the first wire area WLA1 opposite to each other in the first direction (e.g., the x direction or the −x direction). In a plan view, the width DCAw3 of the third driving circuit area DCA3 may be a distance between edges of the third driving circuit area DCA3 opposite to each other in the first direction (e.g., the x direction or the −x direction).

The connection area may include a first intermediate connection area MCA1, a second intermediate connection area MCA2, a third intermediate connection area MCA3, and a fourth intermediate connection area MCA4. The first intermediate connection area MCA1 may extend from the first driving circuit area DCA1 to the first wire area WLA1. The second intermediate connection area MCA2 may extend from the first wire area WLA1 to the third driving circuit area DCA3. The third intermediate connection area MCA3 may extend from the second driving circuit area DCA2 to the second wire area WLA2. The fourth intermediate connection area MCA4 may extend from the second wire area WLA2 to the fourth driving circuit area DCA4.

A circuit layer may be on the substrate 100. The circuit layer may include the first driving circuit DC1, the second driving circuit DC2, a third driving circuit DC3, a fourth driving circuit DC4, the first wire WL1, the second wire WL2, a third wire WL3, and a fourth wire WL4. In an embodiment, each of the first driving circuit DC1 and the second driving circuit DC2 may be a scan driving circuit that generates a scan signal, and each of the third driving circuit DC3 and the fourth driving circuit DC4 may be an emission control driving circuit that generates an emission control signal. In another embodiment, each of the first driving circuit DC1 and the second driving circuit DC2 may be an emission control driving circuit that generates an emission control signal, and each of the third driving circuit DC3 and the fourth driving circuit DC4 may be a scan driving circuit that generates a scan signal.

The first driving circuit DC1 may overlap the first driving circuit area DCA1. The first driving circuit DC1 may include a first conductive pattern CP1. The first conductive pattern CP1 may include a first transistor electrode TC1. The second driving circuit DC2 may overlap the second driving circuit area DCA2. The second driving circuit DC2 may include the second conductive pattern CP2. The second conductive pattern CP2 may include a second transistor electrode TC2.

The shape of the first conductive pattern CP1 and the shape of the second conductive pattern CP2 may be inverted from each other based on the first virtual straight line STL1 passing through the center DCAC1 of the first driving circuit area DCA1 and the center DCAC2 of the second driving circuit area DCA2 in a plan view. In an embodiment, the shape of the first transistor electrode TC1 and the shape of the second transistor electrode TC2 may be inverted from each other based on the first virtual straight line STL1, for example.

The third driving circuit DC3 may overlap the third driving circuit area DCA3. The third driving circuit DC3 may include a third conductive pattern CP3. The third conductive pattern CP3 may include a third transistor electrode TC3. The third transistor electrode TC3 may be an electrode included in a transistor included in the third driving circuit DC3. The fourth driving circuit DC4 may overlap the fourth driving circuit area DCA4. The fourth driving circuit DC4 may include a fourth conductive pattern CP4. The fourth conductive pattern CP4 may include a fourth transistor electrode TC4. The fourth transistor electrode TC4 may be an electrode included in a transistor included in the fourth driving circuit DC4.

The shape of the third conductive pattern CP3 and the shape of the fourth conductive pattern CP4 may be inverted from each other based on the second virtual straight line STL2 passing through the center DCAC3 of the third driving circuit area DCA3 and the center DCAC4 of the fourth driving circuit area DCA4 in a plan view. In an embodiment, the shape of the third transistor electrode TC3 and the shape of the fourth transistor electrode TC4 may be inverted from each other based on the second virtual straight line STL2, for example.

The first wire WL1 may be electrically connected to the first driving circuit DC1. The first wire WL1 may extend from the first driving circuit DC1. The second wire WL2 may be electrically connected to the second driving circuit DC2. The second wire WL2 may extend from the second driving circuit DC2.

The shape of the first wire WL1 in the first driving circuit area DCA1 and the shape of the second wire WL2 in the second driving circuit area DCA2 may be inverted from each other based on the first virtual straight line STL1 passing through the center DCAC1 of the first driving circuit area DCA1 and the center DCAC2 of the second driving circuit area DCA2 in a plan view.

The third wire WL3 may be electrically connected to the third driving circuit DC3. The third wire WL3 may extend from the third driving circuit DC3. In an embodiment, the third wire WL3 and the third transistor electrode TC3 may be unitary. The fourth wire WL4 may be electrically connected to the fourth driving circuit DC4. The fourth wire WL4 may extend from the fourth driving circuit DC4. In an embodiment, the fourth wire WL4 and the fourth transistor electrode TC4 may be unitary.

The shape of the third wire WL3 in the third driving circuit area DCA3 and the shape of the fourth wire WL4 in the fourth driving circuit area DCA4 may be inverted from each other based on the second virtual straight line STL2 passing through the center DCAC3 of the third driving circuit area DCA3 and the center DCAC4 of the fourth driving circuit area DCA4 in a plan view. A portion of the third wire WL3 arranged in the third driving circuit area DCA3 may be on one side of the second virtual straight line STL2. A portion of the fourth wire WL4 arranged in the fourth driving circuit area DCA4 corresponding to a portion of the third wire WL3 may be on the other side of the second virtual straight line STL2.

In the non-display area NDA, the shape of the display device may be repeated in the second direction (e.g., the y direction or the −y direction). A circuit layer may be arranged in a base area according to the shape of the substrate 100 in the non-display area NDA. Therefore, even when an external force is applied to the display device, stress may not be concentrated in the non-display area NDA, and the non-display area NDA may be transformed into various shapes.

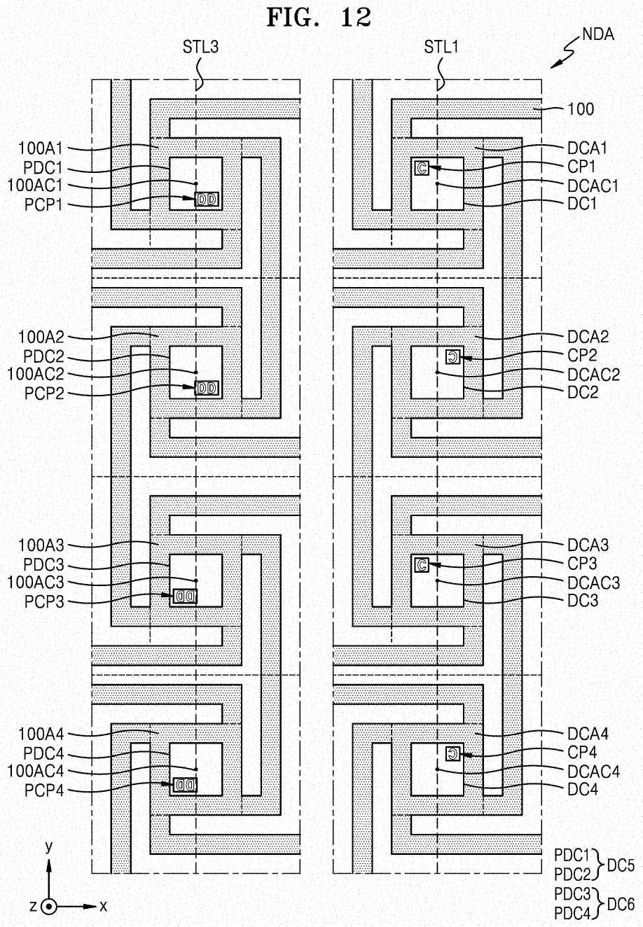

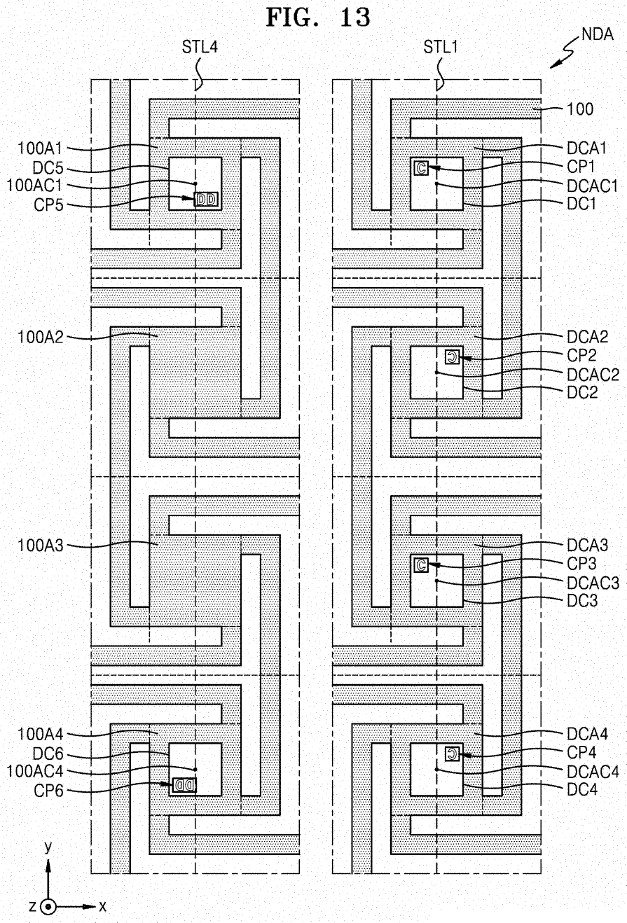

FIG. 12 is a schematic plan view of an embodiment of the non-display area NDA of the display device of FIG. 3. FIG. 13 is a schematic plan view of another embodiment of the non-display area NDA of the display device of FIG. 3.

Referring to FIGS. 12 and 13, the display device may include the substrate 100 and a circuit layer. The substrate 100 may include a display area and the non-display area NDA. The substrate 100 may include a base area, and a connection area, and an opening area may be defined in the substrate 100. The base area may be an area in which components of the display device are arranged. A plurality of base areas may be provided. The plurality of base areas may be spaced apart from each other. The connection area may connect adjacent base areas to each other. A plurality of connection areas may be provided. The opening area may be an area in which components of the display device are not arranged. The opening area may be between adjacent base areas. A plurality of opening areas may be provided. The plurality of opening areas may be spaced apart from each other. The plurality of base areas, the plurality of connection areas, and the plurality of opening areas may be defined in the non-display area NDA.

The base area may include the first driving circuit area DCA1, the second driving circuit area DCA2, the third driving circuit area DCA3, the fourth driving circuit area DCA4, a first base area 100A1, a second base area 100A2, a third base area 100A3, and a fourth base area 100A4.

The first driving circuit area DCA1 and the second driving circuit area DCA2 may be adjacent to each other. The first driving circuit area DCA1 and the second driving circuit area DCA2 may be arranged in the second direction (e.g., the y direction or the −y direction). The third driving circuit area DCA3 and the second driving circuit area DCA2 may be adjacent to each other. The third driving circuit area DCA3 and the second driving circuit area DCA2 may be arranged in the second direction (e.g., the y direction or the −y direction). The fourth driving circuit area DCA4 and the third driving circuit area DCA3 may be adjacent to each other. The fourth driving circuit area DCA4 and the third driving circuit area DCA3 may be arranged in the second direction (e.g., the y direction or the −y direction).

The first virtual straight line STL1 may pass through the center DCAC1 of the first driving circuit area DCA1 and the center DCAC2 of the second driving circuit area DCA2. The third driving circuit area DCA3 may have the center DCAC3 overlapping the first virtual straight line STL1. The fourth driving circuit area DCA4 may have the center DCAC4 overlapping the first virtual straight line STL1.

The first base area 100A1 may be aligned with the first driving circuit area DCA1 in the first direction (e.g., the x direction or the −x direction). The second base area 100A2 may be aligned with the second driving circuit area DCA2 in the first direction (e.g., the x direction or the −x direction). The third base area 100A3 may be aligned with the third driving circuit area DCA3 in the first direction (e.g., the x direction or the −x direction). The fourth base area 100A4 may be aligned with the fourth driving circuit area DCA4 in the first direction (e.g., the x direction or the −x direction). In an embodiment, the first base area 100A1, the second base area 100A2, the third base area 100A3, and the fourth base area 100A4 may be arranged in the second direction (e.g., the y direction or the −y direction).

A circuit layer may be on the substrate 100. The circuit layer may include the first driving circuit DC1, the second driving circuit DC2, the third driving circuit DC3, the fourth driving circuit DC4, a fifth driving circuit DC5, and a sixth driving circuit DC6. In an embodiment, each of the first driving circuit DC1, the second driving circuit DC2, the third driving circuit DC3, and the fourth driving circuit DC4 may be a scan driving circuit that generates a scan signal, and each of the fifth driving circuit DC5 and the sixth driving circuit DC6 may be an emission control driving circuit that generates an emission control signal. In another embodiment, each of the first driving circuit DC1, the second driving circuit DC2, the third driving circuit DC3, and the fourth driving circuit DC4 may be an emission control driving circuit that generates an emission control signal, and each of the fifth driving circuit DC5 and the sixth driving circuit DC6 may be a scan driving circuit that generates a scan signal.

The first driving circuit DC1 may overlap the first driving circuit area DCA1. The first driving circuit DC1 may include the first conductive pattern CP1. The second driving circuit DC2 may overlap the second driving circuit area DCA2. The second driving circuit DC2 may include the second conductive pattern CP2. The shape of the first conductive pattern CP1 and the shape of the second conductive pattern CP2 may be inverted from each other based on the first virtual straight line STL1 passing through the center DCAC1 of the first driving circuit area DCA1 and the center DCAC2 of the second driving circuit area DCA2 in a plan view.

The third driving circuit DC3 may overlap the third driving circuit area DCA3. The third driving circuit DC3 may include a third conductive pattern CP3. The fourth driving circuit DC4 may overlap the fourth driving circuit area DCA4. The fourth driving circuit DC4 may include a fourth conductive pattern CP4. The shape of the third conductive pattern CP3 and the shape of the fourth conductive pattern CP4 may be inverted from each other based on the first virtual straight line STL1 in a plan view.

Referring to FIG. 12, the fifth driving circuit DC5 may include a first partial driving circuit PDC1 and a second partial driving circuit PDC2. In other words, the first partial driving circuit PDC1 and the second partial driving circuit PDC2 may constitute one driving circuit. In an embodiment, the first partial driving circuit PDC1 may be a main circuit portion of the driving circuit, and the second partial driving circuit PDC2 may be a buffer circuit portion of the driving circuit. The main circuit portion may include at least one transistor and at least one storage capacitor, and the buffer circuit portion may include at least one transistor. The buffer circuit portion may not include a storage capacitor. The buffer circuit portion may adjust the magnitude of a signal generated by the main circuit portion.

The first partial driving circuit PDC1 may overlap the first base area 100A1. The first partial driving circuit PDC1 may include a first partial conductive pattern PCP1. The second partial driving circuit PDC2 may overlap the second base area 100A2. The second partial driving circuit PDC2 may include a second partial conductive pattern PCP2.

The sixth driving circuit DC6 may include a third partial driving circuit PDC3 and a fourth partial driving circuit PDC4. In other words, the third partial driving circuit PDC3 and the fourth partial driving circuit PDC4 may constitute one driving circuit. In an embodiment, the third partial driving circuit PDC3 may be a main circuit portion of the driving circuit, and the fourth partial driving circuit PDC4 may be a buffer circuit portion of the driving circuit.

The third partial driving circuit PDC3 may overlap the third base area 100A3. The third partial driving circuit PDC3 may include a third partial conductive pattern PCP3. The fourth partial driving circuit PDC4 may overlap the fourth base area 100A4. The fourth partial driving circuit PDC4 may include a fourth partial conductive pattern PCP4.

The shape of the first partial conductive pattern PCP1 and the shape of the third partial conductive pattern PCP3 may be inverted from each other based on a third virtual straight line STL3 passing through a center 100AC1 of the first base area 100A1 and a center 100AC3 of the third base area 100A3 in a plan view. The shape of the second partial conductive pattern PCP2 and the shape of the fourth partial conductive pattern PCP4 may be inverted from each other based on the third virtual straight line STL3 in a plan view.

In the non-display area NDA, the shape of the display device may be repeated in the second direction (e.g., the y direction or the −y direction). In this case, the fifth driving circuit DC5 and the sixth driving circuit DC6 may be distributed and the area of the base area may not increase.

Referring to FIG. 13, the fifth driving circuit DC5 may overlap the first base area 100A1. The fifth driving circuit DC5 may include a fifth conductive pattern CP5. The sixth driving circuit DC6 may overlap the fourth base area 100A4. The sixth driving circuit DC6 may include a sixth conductive pattern CP6. The shape of the fifth conductive pattern CP5 and the shape of the sixth conductive pattern CP6 may be inverted from each other based on a fourth virtual straight line STL4 passing through the center 100AC1 of the first base area 100A1 and a center 100AC4 of the fourth base area 100A4 in a plan view. In the non-display area NDA, the shape of the display device may be repeated in the second direction (e.g., the y direction or the −y direction). In this case, a desired number of driving circuits may be arranged while maintaining the same number of base areas overlapping the first virtual straight line STL1 as the number of base areas overlapping the fourth virtual straight line STL4. Therefore, even when an external force is applied to the display device, stress may not be concentrated in the non-display area NDA, and the non-display area NDA may be transformed into various shapes.

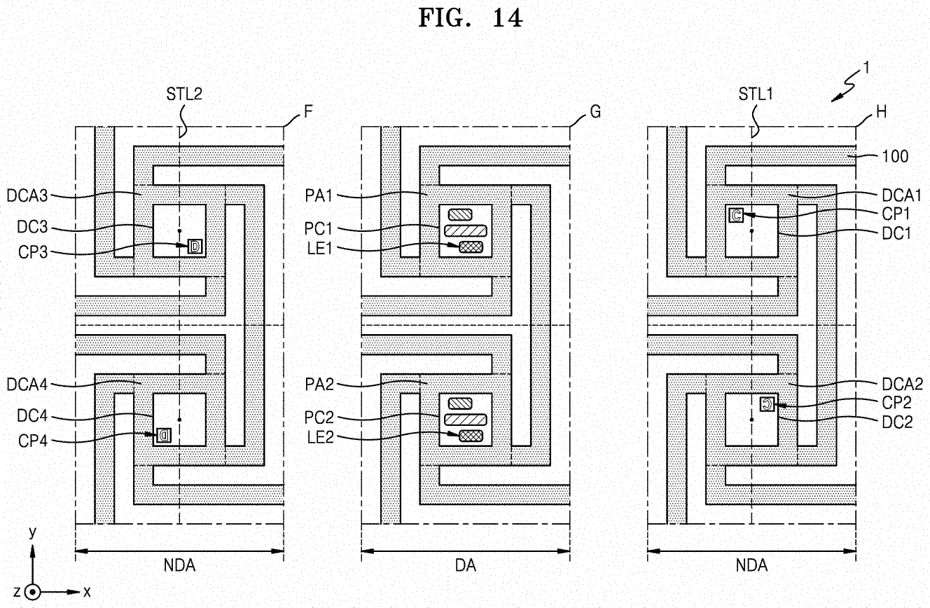

FIG. 14 is an enlarged plan view of portion F, portion G, and portion H of the display device 1 of FIG. 3. In FIG. 14, the same reference numerals as used in FIG. 11 denote the same elements, and a duplicate description will not be given herein.

Referring to FIG. 14, the display device 1 may include the substrate 100, a circuit layer, and a light-emitting device layer. In an embodiment, the substrate 100 may include the display area DA and the non-display area NDA, for example. The substrate 100 may include a base area and a connection area, and an opening area may be defined in the substrate 100. The base area may be an area in which components of the display device 1 are arranged. A plurality of base areas may be provided. The plurality of base areas may be spaced apart from each other. The connection area may connect adjacent base areas to each other. A plurality of connection areas may be provided. The opening area may be an area in which components of the display device are not arranged. A plurality of opening areas may be provided. The plurality of base areas, the plurality of connection areas, and the plurality of opening areas may be defined in the display area DA and/or the non-display area NDA.

The display area DA may include the first pixel area PA1 and the second pixel area PA2. The first pixel area PA1 and the second pixel area PA2 may be adjacent to each other. The first pixel area PA1 and the second pixel area PA2 may be arranged in the second direction (e.g., the y direction or the −y direction).

The non-display area NDA may include the first driving circuit area DCA1, the second driving circuit area DCA2, the third driving circuit area DCA3, and the fourth driving circuit area DCA4. The first driving circuit area DCA1 and the second driving circuit area DCA2 may be adjacent to each other. The first driving circuit area DCA1 and the second driving circuit area DCA2 may be arranged in the second direction (e.g., the y direction or the −y direction).

The third driving circuit area DCA3 may be arranged in the first direction (e.g., the x direction or the −x direction) with the first driving circuit area DCA1. The fourth driving circuit area DCA4 may be arranged in the first direction (e.g., the x direction or the −x direction) with the second driving circuit area DCA2. The fourth driving circuit area DCA4 and the third driving circuit area DCA3 may be adjacent to each other. The third driving circuit area DCA3 and the fourth driving circuit area DCA4 may be arranged in the second direction (e.g., the y direction or the −y direction).

The display area DA may be between the first driving circuit area DCA1 and the third driving circuit area DCA3. In an embodiment, the first pixel area PA1 may be between the first driving circuit area DCA1 and the third driving circuit area DCA3. The display area DA may be between the second driving circuit area DCA2 and the fourth driving circuit area DCA4. In an embodiment, the second pixel area PA2 may be between the second driving circuit area DCA2 and the fourth driving circuit area DCA4.

A circuit layer may be on the substrate 100. The circuit layer may include the first pixel circuit PC1, the second pixel circuit PC2, the first driving circuit DC1, the second driving circuit DC2, the third driving circuit DC3, and the fourth driving circuit DC4. The first pixel circuit PC1 may overlap the first pixel area PA1. The second pixel circuit PC2 may overlap the second pixel area PA2.

In an embodiment, each of the first driving circuit DC1 and the second driving circuit DC2 may be a scan driving circuit that generates a scan signal, and each of the third driving circuit DC3 and the fourth driving circuit DC4 may be an emission control driving circuit that generates an emission control signal. In another embodiment, each of the first driving circuit DC1 and the second driving circuit DC2 may be an emission control driving circuit that generates an emission control signal, and each of the third driving circuit DC3 and the fourth driving circuit DC4 may be a scan driving circuit that generates a scan signal.

The first driving circuit DC1 may overlap the first driving circuit area DCA1. The first driving circuit DC1 may include the first conductive pattern CP1. The second driving circuit DC2 may overlap the second driving circuit area DCA2. The second driving circuit DC2 may include the second conductive pattern CP2. The shape of the first conductive pattern CP1 and the shape of the second conductive pattern CP2 may be inverted from each other based on the first virtual straight line STL1 passing through the center DCAC1 of the first driving circuit area DCA1 and the center DCAC2 of the second driving circuit area DCA2 in a plan view.

The third driving circuit DC3 may overlap the third driving circuit area DCA3. The third driving circuit DC3 may include a third conductive pattern CP3. The fourth driving circuit DC4 may overlap the fourth driving circuit area DCA4. The fourth driving circuit DC4 may include a fourth conductive pattern CP4. The shape of the third conductive pattern CP3 and the shape of the fourth conductive pattern CP4 may be inverted from each other based on the second virtual straight line STL2 passing through the center DCAC3 of the third driving circuit area DCA3 and the center DCAC4 of the fourth driving circuit area DCA4 in a plan view.

A light-emitting device layer may be on a circuit layer. The light-emitting device layer may include a light-emitting device. In an embodiment, the light-emitting device layer may include a first light-emitting device LE1 and a second light-emitting device LE2. The first light-emitting device LE1 may overlap the first pixel area PA1. The first light-emitting device LE1 may be electrically connected to the first pixel circuit PC1. The second light-emitting device LE2 may overlap the second pixel area PA2. The second light-emitting device LE2 may be electrically connected to the second pixel circuit PC2.

In the non-display area NDA, the shape of the display device may be repeated in the second direction (e.g., the y direction or the −y direction). Driving circuits may be arranged in a base area according to the shape of the substrate 100 in the non-display area NDA. Therefore, even when an external force is applied to the display device, stress may not be concentrated in the non-display area NDA, and the non-display area NDA may be transformed into various shapes.

As described above, in a display device in an embodiment, the shape of a first conductive pattern included in a first driving circuit overlapping a first driving circuit area and the shape of a second conductive pattern included in a second driving circuit overlapping a second driving circuit area may be inverted from each other based on a first virtual straight line passing through a center of the first driving circuit area and a center of the second driving circuit area in a plan view. Accordingly, the first driving circuit and the second driving circuit may be arranged according to the shape of the substrate. In this case, even when an external force is applied to the display device, stress may not be concentrated in a non-display area, and the non-display area may be deformed into various shapes without damage.

It should be understood that embodiments described herein should be considered in a descriptive sense only and not for purposes of limitation. Descriptions of features or advantages within each embodiment should typically be considered as available for other similar features or advantages in other embodiments. While embodiments have been described with reference to the drawing figures, it will be understood by those of ordinary skill in the art that various changes in form and details may be made therein without departing from the spirit and scope as defined by the following claims.

What is claimed is:

1. A display device comprising:
a substrate including:
a display area in which a first opening area is defined; and
a non-display area which includes a first driving circuit area and a second driving circuit area adjacent to the first driving circuit area and in which a second opening area is defined between the first driving circuit area and the second driving circuit area; and
a circuit layer disposed on the substrate and including a first driving circuit overlapping the first driving circuit area and including a first conductive pattern, and a second driving circuit overlapping the second driving circuit area and including a second conductive pattern,
wherein a shape of the first conductive pattern and a shape of the second conductive pattern are inverted from each other based on a first virtual straight line passing through a center of the first driving circuit area and a center of the second driving circuit area in a plan view.

2. The display device of claim 1, wherein
the circuit layer further comprises a first wire connected to the first driving circuit and extending from the first driving circuit and a second wire connected to the second driving circuit and extending from the second driving circuit,
wherein a shape of the first wire in the first driving circuit area and a shape of the second wire in the second driving circuit area are inverted from each other based on the first virtual straight line in the plan view.

3. The display device of claim 1, wherein
the non-display area further comprises a third driving circuit area arranged in a first direction with the first driving circuit area and a fourth driving circuit area adjacent to the third driving circuit area and arranged in the first direction with the second driving circuit area,
a third opening area is defined in the non-display area between the third driving circuit area and the fourth driving circuit area, and
the circuit layer further comprises a third driving circuit overlapping the third driving circuit area and including a third conductive pattern and a fourth driving circuit overlapping the fourth driving circuit area and including a fourth conductive pattern,
wherein a shape of the third conductive pattern and a shape of the fourth conductive pattern are inverted from each other based on a second virtual straight line passing through a center of the third driving circuit area and a center of the fourth driving circuit area in the plan view.

4. The display device of claim 3, wherein the non-display area further comprises:
a first wire area between the first driving circuit area and the third driving circuit area,
a first intermediate connection area extending from the first driving circuit area to the first wire area,
a second intermediate connection area extending from the first wire area to the third driving circuit area,
a second wire area between the second driving circuit area and the fourth driving circuit area,
a third intermediate connection area extending from the second driving circuit area to the second wire area, and
a fourth intermediate connection area extending from the second wire area to the fourth driving circuit area,
wherein a width of the first driving circuit area, a width of the first wire area, and a width of the third driving circuit area are the same.

5. The display device of claim 3, wherein
each of the first driving circuit and the second driving circuit is a scan driving circuit which generates a scan signal, and
each of the third driving circuit and the fourth driving circuit is an emission control driving circuit which generates an emission control signal.

6. The display device of claim 3, wherein
the display area further comprises a first pixel area and a second pixel area adjacent to the first pixel area,
the first opening area is between the first pixel area and the second pixel area,
the circuit layer further comprises a first pixel circuit overlapping the first pixel area and a second pixel circuit overlapping the second pixel area, and
the display device further comprises:
a light-emitting device layer disposed on the circuit layer and including a first light-emitting device overlapping the first pixel area and connected to the first pixel circuit and a second light-emitting device overlapping the second pixel area and connected to the second pixel circuit,
wherein the first pixel area is between the first driving circuit area and the third driving circuit area.

7. The display device of claim 1, wherein the non-display area further comprises:
a third driving circuit area having a center overlapping the first virtual straight line and adjacent to the second driving circuit area;
a fourth driving circuit area having a center overlapping the first virtual straight line and adjacent to the third driving circuit area;
a first base area arranged in a first direction with the first driving circuit area;
a second base area arranged in the first direction with the second driving circuit area;
a third base area arranged in the first direction with the third driving circuit area; and
a fourth base area arranged in the first direction with the fourth driving circuit area, and
the circuit layer comprises:
a third driving circuit overlapping the third driving circuit area and including a third conductive pattern;
a fourth driving circuit overlapping the fourth driving circuit area and including a fourth conductive pattern;
a fifth driving circuit including a first partial driving circuit overlapping the first base area and including a first partial conductive pattern, and a second partial driving circuit overlapping the second base area and including a second partial conductive pattern; and
a sixth driving circuit including a third partial driving circuit overlapping the third base area and including a third partial conductive pattern, and a fourth partial driving circuit overlapping the fourth base area and including a fourth partial conductive pattern,
wherein a shape of the first partial conductive pattern and a shape of the third partial conductive pattern are inverted from each other based on a third virtual straight line passing through a center of the first base area and a center of the third base area in the plan view, and
a shape of the second partial conductive pattern and a shape of the fourth partial conductive pattern are inverted from each other based on the third virtual straight line in the plan view.

8. The display device of claim 1, wherein the non-display area further comprises:
a third driving circuit area having a center overlapping the first virtual straight line and adjacent to the second driving circuit area;
a fourth driving circuit area having a center overlapping the first virtual straight line and adjacent to the third driving circuit area;
a first base area arranged in a first direction with the first driving circuit area;
a second base area arranged in the first direction with the second driving circuit area;
a third base area arranged in the first direction with the third driving circuit area; and
a fourth base area arranged in the first direction with the fourth driving circuit area, and
the circuit layer comprises:
a third driving circuit overlapping the third driving circuit area and including a third conductive pattern;
a fourth driving circuit overlapping the fourth driving circuit area and including a fourth conductive pattern;
a fifth driving circuit including a fifth conductive pattern overlapping the first base area; and
a sixth driving circuit including a sixth conductive pattern overlapping the fourth base area,
wherein a shape of the third conductive pattern and a shape of the fourth conductive pattern are inverted from each other based on the first virtual straight line in the plan view, and
a shape of the fifth conductive pattern and a shape of the sixth conductive pattern are inverted from each other based on a fourth virtual straight line passing through a center of the first base area and a center of the fourth base area in the plan view.

9. The display device of claim 1, wherein
the display area further comprises a first pixel area and a second pixel area adjacent to the first pixel area,
the first opening area is between the first pixel area and the second pixel area,
the circuit layer further comprises a first pixel circuit overlapping the first pixel area and a second pixel circuit overlapping the second pixel area, and
the display device further comprises:
a light-emitting device layer disposed on the circuit layer and including a first light-emitting device overlapping the first pixel area and connected to the first pixel circuit and a second light-emitting device overlapping the second pixel area and connected to the second pixel circuit,
wherein a width of the first pixel area is the same as a width of the first driving circuit area.

10. The display device of claim 9, wherein
the display area further comprises a first connection area extending from the first pixel area to the second pixel area; and
the non-display area further comprises a second connection area extending from the first driving circuit area to the second driving circuit area,
wherein, in the plan view, an edge of the first pixel area, an edge of the second pixel area, and an edge of the first connection area define at least a portion of the first opening area, and
in the plan view, an edge of the first driving circuit area, an edge of the second driving circuit area, and an edge of the second connection area define at least a portion of the second opening area,
wherein a width of the first connection area is the same as a width of the second connection area.

11. A display device comprising:
a substrate including:
a display area in which a first opening area is defined; and
a non-display area which includes a first driving circuit area, a second driving circuit area adjacent to the first driving circuit area, and in which a second opening area is defined between the first driving circuit area and the second driving circuit area; and
a circuit layer disposed on the substrate and including a first driving circuit overlapping the first driving circuit area, a first wire connected to the first driving circuit, a second driving circuit overlapping the second driving circuit area, and a second wire connected to the second driving circuit,
wherein a shape of the first wire in the first driving circuit area and a shape of the second wire in the second driving circuit area are inverted from each other based on a first virtual straight line passing through a center of the first driving circuit area and a center of the second driving circuit area in a plan view.

12. The display device of claim 11, wherein
the first driving circuit comprises a first conductive pattern, and
the second driving circuit comprises a second conductive pattern,
wherein a shape of the first conductive pattern and a shape of the second conductive pattern are inverted from each other based on the first virtual straight line in the plan view.

13. The display device of claim 12, wherein
the non-display area further comprises a third driving circuit area arranged in a first direction with the first driving circuit area and a fourth driving circuit area adjacent to the third driving circuit area and arranged in the first direction with the second driving circuit area,
a third opening area is defined in the non-display area between the third driving circuit area and the fourth driving circuit area, and
the circuit layer further comprises a third driving circuit overlapping the third driving circuit area and including a third conductive pattern and a fourth driving circuit overlapping the fourth driving circuit area and including a fourth conductive pattern,
wherein a shape of the third conductive pattern and a shape of the fourth conductive pattern are inverted from each other based on a second virtual straight line passing through a center of the third driving circuit area and a center of the fourth driving circuit area in the plan view.

14. The display device of claim 13, wherein the non-display area further comprises:
a first wire area between the first driving circuit area and the third driving circuit area,
a first intermediate connection area extending from the first driving circuit area to the first wire area,
a second intermediate connection area extending from the first wire area to the third driving circuit area,
a second wire area between the second driving circuit area and the fourth driving circuit area,
a third intermediate connection area extending from the second driving circuit area to the second wire area, and
a fourth intermediate connection area extending from the second wire area to the fourth driving circuit area,
wherein a width of the first driving circuit area, a width of the first wire area, and a width of the third driving circuit area are the same.

15. The display device of claim 13, wherein
each of the first driving circuit and the second driving circuit is a scan driving circuit which generates a scan signal, and
each of the third driving circuit and the fourth driving circuit is an emission control driving circuit which generates an emission control signal.

16. The display device of claim 13, wherein
the display area further comprises a first pixel area and a second pixel area adjacent to the first pixel area,
the first opening area is between the first pixel area and the second pixel area,
the circuit layer further comprises a first pixel circuit overlapping the first pixel area and a second pixel circuit overlapping the second pixel area, and
the display device further comprises:
a light-emitting device layer disposed on the circuit layer and including a first light-emitting device overlapping the first pixel area and connected to the first pixel circuit and a second light-emitting device overlapping the second pixel area and connected to the second pixel circuit,
wherein the first pixel area is between the first driving circuit area and the third driving circuit area.

17. The display device of claim 12, wherein the non-display area further comprises:
a third driving circuit area having a center overlapping the first virtual straight line and adjacent to the second driving circuit area;
a fourth driving circuit area having a center overlapping the first virtual straight line and adjacent to the third driving circuit area;
a first base area arranged in a first direction with the first driving circuit area;
a second base area arranged in the first direction with the second driving circuit area;
a third base area arranged in the first direction with the third driving circuit area; and
a fourth base area arranged in the first direction with the fourth driving circuit area, and
the circuit layer comprises:
a third driving circuit overlapping the third driving circuit area and including a third conductive pattern;
a fourth driving circuit overlapping the fourth driving circuit area and including a fourth conductive pattern;
a fifth driving circuit including a first partial driving circuit overlapping the first base area and including a first partial conductive pattern and a second partial driving circuit overlapping the second base area and including a second partial conductive pattern; and
a sixth driving circuit including a third partial driving circuit overlapping the third base area and including a third partial conductive pattern and a fourth partial driving circuit overlapping the fourth base area and including a fourth partial conductive pattern,
wherein a shape of the first partial conductive pattern and a shape of the third partial conductive pattern are inverted from each other based on a third virtual straight line passing through a center of the first base area and a center of the third base area in the plan view, and
a shape of the second partial conductive pattern and a shape of the fourth partial conductive pattern are inverted from each other based on the third virtual straight line in the plan view.

18. The display device of claim 12, wherein the non-display area further comprises:
a third driving circuit area having a center overlapping the first virtual straight line and adjacent to the second driving circuit area;
a fourth driving circuit area having a center overlapping the first virtual straight line and adjacent to the third driving circuit area;
a first base area arranged in a first direction with the first driving circuit area;
a second base area arranged in the first direction with the second driving circuit area;
a third base area arranged in the first direction with the third driving circuit area; and
a fourth base area arranged in the first direction with the fourth driving circuit area, and
the circuit layer comprises:
a third driving circuit overlapping the third driving circuit area and including a third conductive pattern;
a fourth driving circuit overlapping the fourth driving circuit area and including a fourth conductive pattern;
a fifth driving circuit including a fifth conductive pattern overlapping the first base area; and
a sixth driving circuit including a sixth conductive pattern overlapping the fourth base area,
wherein a shape of the third conductive pattern and a shape of the fourth conductive pattern are inverted from each other based on the first virtual straight line in the plan view, and
a shape of the fifth conductive pattern and a shape of the sixth conductive pattern are inverted from each other based on a fourth virtual straight line passing through a center of the first base area and a center of the fourth base area in the plan view.

19. The display device of claim 11, wherein
the display area further comprises a first pixel area, a second pixel area adjacent to the first pixel area, and a first connection area extending from the first pixel area to the second pixel area, and
the non-display area further comprises a second connection area extending from the first driving circuit area to the second driving circuit area,
wherein, in the plan view, an edge of the first pixel area, an edge of the second pixel area, and an edge of the first connection area define at least a portion of the first opening area, and
in the plan view, an edge of the first driving circuit area, an edge of the second driving circuit area, and an edge of the second connection area define at least a portion of the second opening area,
the circuit layer further comprises a first pixel circuit overlapping the first pixel area and a second pixel circuit overlapping the second pixel area, and
the display device further comprises:
a light-emitting device layer disposed on the circuit layer and including a first light-emitting device overlapping the first pixel area and connected to the first pixel circuit and a second light-emitting device overlapping the second pixel area and connected to the second pixel circuit,
wherein, in the plan view, a width of the first pixel area, a width of the second pixel area, a width of the first driving circuit area, and a width of the second driving circuit area are the same as each other, and
a width of the first connection area is the same as a width of the second connection area.

20. The display device of claim 19, wherein
the circuit layer further comprises a first planarization layer overlapping the second connection area and a second planarization layer disposed on the first planarization layer, and
the first wire extends from the first driving circuit area to the second connection area and is between the first planarization layer and the second planarization layer.
